(19) United States
(12) Patent Application Publication
(10) Pub. No.: US 2025/0157978 A1
(43) Pub. Date: May 15, 2025

(54) CHIP TRANSFER DEVICE, CHIP TRANSFER METHOD AND MAGNETIC DIE BONDING PEN

(71) Applicants: BOE MLED Technology Co., Ltd., Beijing (CN); BOE Technology Group Co., Ltd., Beijing (CN)

(72) Inventors: Wei Zhang, Beijing (CN); Pengju Hu, Beijing (CN); Huan Tang, Beijing (CN); Yang Yu, Beijing (CN)

(21) Appl. No.: 18/832,535

(22) PCT Filed: May 8, 2023
(86) PCT No.: PCT/CN2023/092722

§ 371 Date: Jul. 24, 2024

(51) Int. Cl. H01L 23/00; H01L 21/67; H10H 29/02

(52) U.S. Cl. CPC H01L 24/75; H01L 21/67144; H10H 29/02; H01L 2224/75652

(57) ABSTRACT

The present disclosure provides a chip transfer device, comprising: a transmission chain loop passing through pickup position(s) and put-down position(s); a driving gear cooperating with the transmission chain loop; and a plurality of pickup components disposed on the transmission chain loop, wherein the driving gear is configured to drive the transmission chain loop such that the pickup components arrive at the pickup positions and the put-down positions, and the pickup component is configured to pick up a chip at a pickup position and put down the chip at a put-down position. The present disclosure also provides a chip transfer method and a magnetic die bonding pen.

### TECHNICAL FIELD

The present disclosure relates to the field of die bonding device, and particularly to a chip transfer device, a chip transfer method and a magnetic die bonding pen.

### BACKGROUND

Die bonding is an important process in the semiconductor industry and electronics industry. Die bonding initially refers to a process for mounting a wafer into an integrated circuit. With continuous development of the semiconductor industry and electronics industry, some processes similar to that process are also referred to as “die bonding”, such that the meaning of die bonding is continuously extended. The meaning of the term “die bonding” is not limited to the mounting of a wafer, but also extended to the mounting of various small size objects including chips (such as light-emitting chips).

For example, in the semiconductor integrated circuit (IC) industry, an IC die bonder may be used for mounting a wafer into an IC. Typically, after a chip array is obtained by dividing a circular wafer, in an IC die bonder, a chip is picked up from the chip array of the wafer by a die bonding head, the die bonding head with the chip is then transferred to and aligned with a target position on a target substrate, and finally, the chip is released from the die bonding head and mounted onto the target substrate by a manner of welding or the like. The die bonding head generally realizes the pickup and release of the chip through a suction nozzle.

It is necessary for this type of die bonder as described above to accurately pick up the chip to the die bonding head and then accurately transfer the die bonding head to the target position on the target substrate. Currently, in order to complete such an operation, it is generally necessary to use a swing-arm-type robot arm structure. The swing of the robot arm about its shaft drives the swing of the die bonding head between the pickup (chip picking up) position and the die bonding (chip placement) position, thereby achieving the transfer of the die bonding object from the initial substrate to the target substrate.

There is still a need for improving the die bonding device.

### SUMMARY

In an aspect, the present disclosure provides a chip transfer device comprising:
a transmission chain loop passing through pickup position(s) and put-down position(s);
a driving gear cooperating with the transmission chain loop; and
a plurality of pickup components disposed on the transmission chain loop,
wherein the driving gear is configured to drive the transmission chain loop such that the pickup components arrive at the pickup positions and the put-down positions, and the pickup component is configured to pick up a chip at a pickup position and put down the chip at a put-down position.

Optionally, the transmission chain loop passes through at least one group of put-down positions comprising a plurality of put-down positions on a first straight line.

Optionally, the chips includes light-emitting chips serving as sub-pixels of a display device, wherein the light-emitting chips include first light-emitting chips,
the chip transfer device is configured to transfer the first light-emitting chips from a first initial substrate to a first target substrate, such that the first light-emitting chips are periodically arranged on the first target substrate along a first direction,
the first straight line extends along the first direction, and
a distance between two adjacent put-down positions in the group of put-down positions is equal to an integer multiple of an arrangement period of the first light-emitting chips.

Optionally, the transmission chain loop passes through at least one group of pickup positions comprising a plurality of pickup positions on a second straight line.

Optionally, the chip transfer device is configured to transfer the chips from a first initial substrate to a first target substrate, such that the chips are periodically arranged on the first initial substrate along a second direction,
the second straight line extends along the second direction, and
a distance between two adjacent pickup positions in the group of pickup positions is equal to an integer multiple of an arrangement period of the chips.

Optionally, the chip includes light-emitting chips serving as sub-pixels of a display device, wherein the light-emitting chips include first light-emitting chips and second light-emitting chips, and the first light-emitting chips and the second light-emitting chips have different luminous colors,
the chip transfer device is configured to transfer the first light-emitting chips from a first initial substrate to a first target substrate, and transfer the second light-emitting chips from a second initial substrate to the first target substrate,
the chip transfer device comprises a first supporting area and a second supporting area, wherein the chip transfer device supports the first initial substrate in the first supporting area, and the chip transfer device supports the second initial substrate in the second supporting area,
a portion of the pickup positions are located in the first supporting area, and a portion of the pickup positions are located in the second supporting area,
the chip transfer device comprises a target-supporting area, wherein the chip transfer device supports the first target substrate in the target-supporting area, and the put-down position(s) are located in the target-supporting area, and
the transmission chain loop is configured to drive the plurality of pickup components to sequentially pass through the first supporting area, the second supporting area and the first target-supporting area.

Optionally, the light-emitting chips further include third light-emitting chips, wherein the first light-emitting chips, the second light-emitting chips and the third light-emitting chips have different luminous colors,
the chip transfer device is configured to further transfer the third light-emitting chips from a third initial substrate to the first target substrate,
the chip transfer device further comprises a third supporting area, wherein the chip transfer device supports the third initial substrate in the third supporting area; and a portion of the pickup positions are located in the third supporting area, and
the transmission chain loop is configured to drive the plurality of pickup components to sequentially pass through the first supporting area, the second supporting area, the third supporting area and the first target-supporting area.

Optionally, the chip includes light-emitting chip serving as sub-pixels of a display device, wherein the light-emitting chips include first light-emitting chips and second light-emitting chips, and the first light-emitting chip and the second light-emitting chip have the same luminous color,
the chip transfer device is configured to transfer the first light-emitting chips from a first initial substrate to a first target substrate, and transfer the second light-emitting chips from a second initial substrate to the first target substrate,
the chip transfer device comprises a first supporting area and a second supporting area, wherein the chip transfer device supports the first initial substrate in the first supporting area, and the chip transfer device supports the second initial substrate in the second supporting area,
a portion of the pickup positions are located in the first supporting area, and a portion of the pickup positions are located in the second supporting area,
the chip transfer device comprises a target-supporting area, wherein the chip transfer device supports the first target substrate in the target-supporting area, and the put-down position(s) are located in the first target-supporting area, and
the transmission chain loop is configured to drive the plurality of pickup components to sequentially pass through the first supporting area, the second supporting area and the first target-supporting area.

Optionally, the chip transfer device is configured to transfer first chips from a fourth initial substrate to a second target substrate, and transfer second chips from a fifth initial substrate to a third target substrate,
the chip transfer device comprises a fourth supporting area and a fifth supporting area, where in the chip transfer device supports the fourth initial substrate in the fourth supporting area, and the chip transfer device supports the fifth initial substrate in the fifth supporting area,
the chip transfer device further comprises a second target-supporting area and a third target-supporting area, wherein the chip transfer device supports the second target substrate in the second target-supporting area, and the chip transfer device supports the third target substrate in the third target-supporting area,
a portion of the pickup positions are located in the fourth supporting area, and a portion of the pickup positions are located in the fifth supporting area,
a portion of the put-down positions are located in the second target-supporting area, and a portion of the put-down positions are located in the third target-supporting area,
wherein
the transmission chain loop is configured to drive the plurality of pickup components to sequentially pass through the fourth supporting area, the fifth supporting area, the second target-supporting area and the third target-supporting area, or sequentially pass through the fourth supporting area, the second target-supporting area, the fifth supporting area and the third target-supporting area.

Optionally, the chip transfer device comprises a first movable stage which is disposed to correspond to the put-down positions.

Optionally, the chip transfer device comprises a second movable stage which is disposed to correspond to the pickup positions.

Optionally, the chip transfer device further comprises a rotatable negative pressure gas cylinder, wherein the rotatable negative pressure gas cylinder has an internal cavity;
the internal cavity of the rotatable negative pressure gas cylinder is connected to the pickup components through a pipeline, and is configured to provide a negative pressure to the pickup components; and
the rotatable negative pressure gas cylinder is rotated by movement of the pickup components via the pipeline.

Optionally, the chip transfer device further comprises:
a fixed cylinder, wherein the fixed cylinder has an internal cavity in gas communication with a negative pressure air pipe, and the fixed cylinder comprises a recess formed by inward extending of an inner wall; and
a plurality of balls;
wherein
the rotatable negative pressure gas cylinder is sleeved in the fixed cylinder, and has a first end away from the negative pressure air pipe and a second end close to the negative pressure air pipe, and the internal cavity of the rotatable negative pressure gas cylinder communicates the first end and the second end;
an outer side wall of the rotatable negative pressure gas cylinder comprises a protrusion which is fitted into the recess,
the internal cavity of the rotatable negative pressure gas cylinder is slidably joined to the internal cavity of the fixed cylinder, and is sealed at a joint with a seal ring,
the rotatable negative pressure gas cylinder has a plurality of pipeline connection ports at the first end for connecting to the pipeline, and
the recess and the protrusion have opposite grooves forming a first groove structure, and the first groove structure serves as a first sliding track to accommodate the balls to form a ball bearing.

Optionally, the recess and the protrusion also have opposite grooves forming a second groove structure, and the second groove structure serves as a second sliding track to accommodate the balls to form a ball bearing, wherein the first sliding track and the second sliding track are respectively located on a side of the recess close to the first end and a side of the recess close to the second end.

Optionally, opposite grooves forming a third groove structure are provided respectively on the outer side wall of the rotatable negative pressure gas cylinder and the inner wall of the fixed cylinder, and the third groove structure accommodates the seal ring surrounding the rotatable negative pressure gas cylinder.

Optionally, the seal ring is further away from the first end than the protrusion.

Optionally, the pickup positions and the put-down positions are provided with an electromagnetic pickup component positioner,
wherein
the electromagnetic pickup component positioner has a second magnetic component, and
the pickup component has a first magnetic component, such that when the first magnetic component is attracted by the second magnetic component, the pickup component is temporarily fixed to the electromagnetic die bonding pen positioner,
wherein at least one of the first magnetic component and the second magnetic component is an electromagnetic component.

Optionally, the electromagnetic pickup component positioner has a recessed bottom and the pickup component has a protruded top, or, the electromagnetic pickup component positioner has a protruded bottom and the pickup component has a recessed top, such that when the second magnetic component is attracted by the first magnetic component, an outer surface of the top of the pickup component is adjacent to an inner surface of the bottom of the electromagnetic pickup component positioner, and preferably both the bottom and the top have a circular truncated cone-shaped structure.

Optionally, the chip transfer device is a Micro LED chip transfer device or a Mini LED chip transfer device.

Optionally, the driving gear is a stepping gear.

Optionally, the chip is a wafer or comprises a wafer.

In another aspect, the present disclosure provides a chip transfer method comprising:
driving a transmission chain loop with a plurality of pickup components fixed to pass through pickup position(s) and put-down position(s) with a driving gear, such that the pickup components arrive at the pickup positions and the put-down positions, and
picking up a chip at the pickup position, and putting down the chip at the put-down position.

Optionally, the transmission chain loop passes through at least one group of put-down positions comprising a plurality of put-down positions on a first straight line,
wherein chips are put down respectively at the put-down positions of the group of put-down positions simultaneously.

Optionally, the chip includes light-emitting chips serving as sub-pixels of a display device, wherein the light-emitting chips include first light-emitting chips having the same luminous color,
the chip transfer method further comprises transferring the first light-emitting chips from a first initial substrate to a first target substrate, such that the first light-emitting chips are periodically arranged on the first target substrate along a first direction,
the first straight line extends along the first direction, and
a distance between two adjacent put-down positions in the group of put-down positions is equal to an integer multiple of an arrangement period of the first light-emitting chips.

Optionally, the transmission chain loop passes through at least one group of pickup positions comprising a plurality of pickup positions on a second straight line.

Optionally, the chip transfer method further comprises transferring the chips from a first initial substrate to a first target substrate, such that the chips are periodically arranged on the first initial substrate along a second direction;
the second straight line extends along the second direction; and
a distance between two adjacent pickup positions in the group of pickup positions is equal to an integer multiple of an arrangement period of the chips.

Optionally, the chip includes light-emitting chips serving as sub-pixels of a display device, wherein the light-emitting chips include first light-emitting chips and second light-emitting chips, and the first light-emitting chips and the second light-emitting chips have different luminous colors,
the chip transfer method further comprises transferring the first light-emitting chips from a first initial substrate to a first target substrate, and transferring the second light-emitting chips from a second initial substrate to the first target substrate,
the first initial substrate is supported in a first supporting area, the second initial substrate is supported in a second supporting area, and the first target substrate is supported in a first target-supporting area,
a portion of the pickup positions are located in the first supporting area, a portion of the pickup positions are located in the second supporting area, and the put-down position(s) are located in the first target-supporting area, and
the chip transfer method further comprises driving the plurality of pickup components to sequentially pass through the first supporting area, the second supporting area and the first target-supporting area with the transmission chain loop.

Optionally, the light-emitting chip further comprises a third light-emitting chip, wherein the first light-emitting chips, the second light-emitting chips and the third light-emitting chips have different luminous colors,
the chip transfer method further comprises transferring the third light-emitting chips from a third initial substrate to the first target substrate,
the third initial substrate is supported in a third supporting area, and a portion of the pickup positions are located in the third supporting area, and
the chip transfer method further comprises driving the plurality of pickup components to sequentially pass through the first supporting area, the second supporting area, the third supporting area and the first target-supporting area with the transmission chain loop.

Optionally, the chip includes light-emitting chips serving as sub-pixels of a display device, wherein the light-emitting chips include first light-emitting chips and second light-emitting chips, and the first light-emitting chips and the second light-emitting chips have the same luminous color,
the chip transfer method further comprises transferring the first light-emitting chips from a first initial substrate to a first target substrate, and transferring the second light-emitting chip from a second initial substrate to the first target substrate,
the first initial substrate is supported in a first supporting area, the second initial substrate is supported in a second supporting area, and the first target substrate is supported in a first target-supporting area,
a portion of the pickup positions are located in the first supporting area, a portion of the pickup positions are located in the second supporting area, and the put-down position(s) are located in the first target-supporting area, and
the chip transfer method further comprises driving the plurality of pickup components to sequentially pass through the first supporting area, the second supporting area and the first target-supporting area with the transmission chain loop.

Optionally, the chip transfer method further comprises transferring first chips from a fourth initial substrate to a second target substrate, and transferring second chips from a fifth initial substrate to a third target substrate,
the fourth initial substrate is supported in a fourth supporting area, the fifth initial substrate is supported in a fifth supporting area, and the second target substrate is supported in a first target-supporting area,
a portion of the pickup positions are located in the fourth supporting area, and a portion of the pickup positions are located in the fifth supporting area,
a portion of the put-down positions are located in the second target-supporting area, and a portion of the put-down positions are located in the third target-supporting area,
wherein
the chip transfer method further comprises driving the plurality of pickup components to sequentially pass through the fourth supporting area, the fifth supporting area, the second target-supporting area and the third target-supporting area, or, sequentially pass through the fourth supporting area, the second target-supporting area, the fifth supporting area and the third target-supporting area.

Optionally, a position of the pickup component is fixed with a positioner after the pickup component arrives at the pickup position;
the chip is aligned with the position of the pickup component by using an automated optical inspection machine, and
the chip is picked up,
and
a position of the pickup component is fixed with a positioner after the pickup component arrives at a put-down position;
a put-down target is aligned with the position of the pickup component by using an automated optical inspection machine; and
the chip is put down at the put-down target.

Optionally, picking up the chip comprises applying a negative pressure to the pickup component to take the chip by suction, and
putting down the chip comprises contacting the chip with a solder paste and removing the negative pressure.

Optionally, the driving gear drives the transmission chain loop step by step.

Optionally, the chip is a wafer or comprises a wafer.

In yet another aspect, the present disclosure provides a magnetic die bonding pen comprising:
a tubular pen cylinder, and
a columnar pen core in the tubular pen cylinder, the columnar pen core having a first end, a second end and a side wall extending between the first end and the second end,
wherein the columnar pen core comprises:
   a first magnetic component which is a permanent magnetic component or comprises a metal capable of being attracted by a magnet;
   a suction nozzle at the first end,
   a pipeline connector on the side wall, and
   a gas path extending inside the side wall and connecting the suction nozzle and the pipeline connector.

Optionally, the magnetic die bonding pen further comprises a convex or concave structure, and preferably a circular truncated cone-shaped convex or concave structure, at the second end.

Optionally, the magnetic die bonding pen further comprises:
a restoring spring forming an axial connection between the tubular pen cylinder and the columnar pen core.

Optionally, a side wall of the tubular pen cylinder has an axially extending groove, and
the pipeline connector passes through the groove to an outside of the tubular pen cylinder.

Optionally, an electromagnetic valve is provided at the pipeline connector outside the tubular pen cylinder.

### BRIEF DESCRIPTION OF DRAWINGS

FIG. 1 shows a top view of an embodiment of a chip transfer device according to the present disclosure.

FIG. 2 shows a perspective view of the embodiment of FIG. 1.

FIG. 3 schematically shows a schematic diagram of a chip array and a corresponding arrangement of sites where the chips are to be placed.

FIG. 4 shows a schematic diagram of an embodiment in which two groups of pickup positions and two groups of put-down positions are provided.

FIG. 5 shows a schematic diagram of an embodiment of a fixed cylinder and a rotatable negative pressure gas cylinder cooperating with each other.

FIG. 6 shows a schematic diagram of a magnetic die bonding pen and an electromagnetic die bonding pen positioner cooperating therewith.

FIG. 7 shows a schematic diagram of an arrangement of an embodiment according to the present disclosure.

FIG. 8 shows a schematic diagram of an arrangement of another embodiment according to the present disclosure.

FIG. 9 shows a schematic diagram of an arrangement of another embodiment according to the present disclosure.

FIG. 10 shows a schematic diagram of an arrangement of another embodiment according to the present disclosure.

### DETAILED DESCRIPTION

Die bonding devices in related technologies use a robot arm to achieve the transfer of a die bonding head from a chip pickup position on an initial substrate to a die bonding position on a target substrate. A common robot arm is a swing robot arm which is a robot arm having a length and rotating about a typically vertical fixed rotation axis. The distance between the chip pickup position and the rotation axis is the same as the distance between the die bonding position and the rotation axis. After the die bonding head picks up a chip at the chip pickup position, the robot arm rotates about the rotation axis by an angle, so as to move the die bonding head to the die bonding position. After the die bonding head puts down the chip at the die bonding position and completes the die bonding, the robot arm rotates back to the chip pickup position, thereby completing a swing, i.e., a chip pickup-die bonding cycle. The stages supporting the initial substrate and the target substrate are respectively displaced slightly to provide a new chip to the chip pickup position and prepare a new site for die bonding at the die bonding position, so as to start the next chip pickup-die bonding cycle.

It should be understood that in the present disclosure, the terms “die bonding”, “chip pickup”, “die bonding position”, “chip pickup position”, “chip pickup-die bonding cycle”, “die bonding pen”, “die bonding pen positioner” and the like related to wafers are also applicable to chips, such as a light-emitting chip, unless the context specifically indicates otherwise. The chip may be a wafer or comprises a wafer.

The inventors have found that although swinging robot arms may achieve high positioning accuracy, the overall speed is low and the die bonding efficiency is low, which directly influences the production capacity. Typically, the chip pickup position and the die bonding position are respectively located at two ends of a diameter in the rotating plane of the robot arm passing through the rotation axis. In each chip pickup-die bonding cycle, the die bonding head needs to perform a round trip movement between the chip pickup position and the die bonding position along the circumference. Because the chip pickup position should not be too close to the die bonding position so as to avoid the mutual interference between the support stage for the initial substrate and the support stage for the target substrate, the distance travelled by the above round trip movement is relatively long. This takes a large amount of time, resulting in low speed. Due to the relatively long distance, in order to reduce the tact time (TT) and the cycle time, higher acceleration and deceleration can be applied to the robot arm respectively at starting and stopping of rotation. However, because the robot arm generally has a relatively large weight, this may result in poor mechanical stability of the system, which may in turn reduce the accuracy. Another attempt to save time is to provide a plurality of alternate chip pickup positions and die bonding positions in the movement plane around the rotation axis, such that the angle of each rotation of the robot arm is less than 180°. However, such an approach has to provide a separate robot arm for each of the chip pickup positions and the die bonding positions, which increases the complexity of the device. Also, such an approach in turn leads to crowding of the chip pickup positions and the die bonding positions, so that the distance between the die bonding head and the rotation axis may have to be increased. The increased distance greatly counteracts the increased densities of the chip pickup positions and die bonding positions, resulting in little improvement in the overall speed. Also, a longer robot arm requires a larger circular working area, which will also take up more space.

The present disclosure may at least partially solve the problem of low overall speed of the swing-arm-type die bonding device.

In an embodiment, the present disclosure provides a chain-type die bonding device (which may specifically be a chip transfer device), comprising:
a transmission chain loop passing through one or more chip pickup positions (which may also be referred to as pickup positions) and one or more die bonding positions (which may also be referred to as put-down positions);
a driving gear (which may specifically be a stepping gear) cooperating with the transmission chain loop, and
a plurality of die bonding pens (which may also be referred to as pickup components) disposed on the transmission chain loop.

Completely different from the swing-arm-type die bonding device in the related technologies which performs the transfer of a die bonding head based on a rotating robot arm, the die bonding device of the present disclosure is a chain-type die bonding device which performs the transfer of a die bonding pen based on a transmission chain loop.

The chain-type die bonding device of the present disclosure comprises a transmission chain loop, a driving gear and a plurality of die bonding pens. The plurality of die bonding pens are disposed on the transmission chain loop, and move in the path of the transmission chain loop with the movement of the transmission chain loop driven by the driving gear. In particular, when the driving gear is a stepping gear, the die bonding pen moves in the path of the transmission chain loop step by step.

The transmission chain loop passes through one or more chip pickup positions and one or more die bonding positions. Therefore, the die bonding pens disposed on the transmission chain loop may be transferred between those chip pickup positions and the die bonding positions to achieve chip pickup and die bonding.

The movement (especially step by step movement) of the plurality of die bonding pens with the transmission chain provides several advantages, including but not limited to increasing the overall speed of the die bonding device and improving the die bonding efficiency, thereby increasing the production capacity.

Providing the plurality of die bonding pens on the transmission chain loop may make full use of the space in the working plane. As described above, the transmission chain loop is configured to pass through one or more chip pickup positions and one or more die bonding positions.

In an embodiment, in an example where the transmission chain loop passes through one chip pickup position and one die bonding position, because the path is a loop, there are two continuous transmission chain segments between the chip pickup position and the die bonding position, i.e., a segment from the chip pickup position to die bonding position and a segment from the die bonding position to the chip pickup position along the transmission chain movement direction. In the path of the transmission chain loop, a plurality of die bonding pens are also provided in those segments outside the chip pickup position and the die bonding position. Therefore, when the die bonding pen on the transmission chain loop at the chip pickup position or the die bonding position carries out a chip pickup action or a die bonding action, the other die bonding pens on the above transmission chain segments may be in a “queuing” state. As the gear drives the transmission chain loop to advance, the die bonding pen completing the chip pickup action or the die bonding action leaves the chip pickup position or the die bonding position, while the die bonding pen in the “queuing” state may subsequently arrive at the chip pickup position or the die bonding position. Taking the chip pickup process as an example, after the die bonding pen at the chip pickup position leaves, through such a “queuing” mechanism, the next die bonding pen which will arrive at the chip pickup position does not move to the chip pickup position directly from the die bonding position, but moves to the chip pickup position from a position closest to the chip pickup position in the die bonding pen queue lined in the segment between the die bonding position and the chip pickup position. Therefore, the distance at which the die bonding pen needs to move is greatly reduced, and the time required between two chip pickup actions may also be greatly reduced accordingly. When the driving gear is a stepping gear, the time may be as short as the time required for the stepping gear to advance one step as described below. The same is true for the die bonding process. In other words, the die bonding pen needs not to switch between the chip pickup position and the die bonding position over a long tact time, but may approach the target position gradually over several short tact times. In each short tact time, there may be a die bonding pen supplied to the chip pickup position or the die bonding position. Therefore, as compared to the swing-arm-type die bonding device where the die bonding head needs to be moved directly from the chip pickup position to the die bonding position in each tact time, the chain-type die bonding device of the present disclosure may save a large amount of time, thereby greatly increasing the overall speed.

The inventors have also found that the arrangement density of the die bonding heads of the swing-arm-type die bonding device is significantly limited by the circular path, the robot arm number, the interference between the devices and the like, and is much lower than the arrangement density of the die bonding pens which may be achieved on the transmission chain loop. Therefore, even for a chain-type die bonding device of the present disclosure having the transmission chain loop only passes through one chip pickup position and one die bonding position, not only significantly saves time as compared to the swing-arm-type die bonding device having only one chip pickup position and one die bonding position, but also saves time as compared to the aforementioned swing-arm-type die bonding device where a plurality of alternate chip pickup positions and die bonding positions are provided on the circumference around the rotation axis in the movement plane.

Also, in the present disclosure, the transmission chain loop may also be configured to pass through a plurality of chip pickup positions and/or a plurality of die bonding positions. In the case of the same perimeter of the transmission chain loop, providing a plurality of chip pickup positions and/or a plurality of die bonding positions may further increase the overall speed as compared to providing one chip pickup position and one die bonding position. In an embodiment, the plurality of chip pickup positions may provide different types of chips, and/or the plurality of die bonding positions may provide different types of target substrates, such that the die bonding pen may complete various different die bonding processes during one cycle along the loop so as to further utilize space and increase the efficiency.

In addition to increasing the overall speed, the benefits of using the transmission chain loop may also include flexibility in setting the loop shape. Therefore, the moving route of the die bonding pen may be arbitrary, and does not have to be circular. Also, in the case of the same perimeter, as compared to the circle which takes up the largest area, the transmission chain loop may take up a relatively smaller area. Furthermore, the support stages for the target substrate and the initial substrate (which may also referred to as a first movable stage and a second movable stage) cooperating therewith may also be arranged at any suitable position on the transmission chain loop, and does not have to be arranged at the same distance from the rotation axis, thereby increasing the flexibility in device layout.

Furthermore, because the distance at which the die bonding pen needs to move each time is greatly reduced, and no large weight robot arm is used, this is very beneficial for the mechanical stability of the system.

The chain is also characterized in that it is composed of a plurality of substantially rigid chain segments which are combined by articulating. Therefore, as compared to a transmission structure such as a belt which achieves the flexibility through elastic deformation, the chain provides much more accurate positioning for the die bonding pen disposed thereon.

The specific type and size of the transmission chain are not particularly limited in the present disclosure.

The chain-type die bonding device of the present disclosure comprises a driving gear cooperating with the transmission chain loop. The cooperation of the transmission chain with the gear is well known in the mechanical field. Typically, the transmission chain may be engaged with a chain wheel. The present disclosure preferably uses a stepping gear, which may rotate at the same angle each time, and drive the transmission chain cooperating therewith to advance the same distance each time, or advance one step. Accordingly, the die bonding pen disposed on the transmission chain also advances one step along the transmission chain loop, thereby achieving the stepping along the loop. As compared to non-stepping transmission (such as belt transmission) driven by another mechanical driving device such as a motor, the positions where the die bonding pen arrives at by each advance are fixed, so as long as the chip pickup positions and the die bonding positions are provided at some of those fixed positions, the die bonding pen may be directly positioned at the chip pickup positions and the die bonding positions, thereby achieving efficient positioning and easy control.

The stepping gear provides a driving force for the movement of the transmission chain. The stepping gear may have a number of one or more, and may be disposed inside the transmission chain loop. In order to maintain proper tension of the chain, one or more tensioning gears which cooperate with the transmission chain and passively rotated may be provided. It may be understood that various stepping gear and tensioning gear configurations which can provide stable shape of the transmission chain loop may be used without departing from the spirit of the present disclosure.

The die bonding pen may be sometimes referred to as a die bonding head, or more generally, a pickup component. Typically, it has a pen body disposed on the chain transmission loop and a pen tip for picking up a chip by suction. In an embodiment, the pen body may be perpendicular to a horizontal transmission chain loop plane, and thus the pen tip may be located directly below the transmission chain loop. In another embodiment, the pen body may be configured to be at an angle with respect to the transmission chain plane, and thus the trajectory of the pen tip forms a similar shape to the transmission chain loop. The sizes and shapes of the pen tip and pen body are not particularly limited, as long as smooth and stable chip pickup/die bonding actions can be achieved when the die bonding pen is disposed on the transmission chain.

In an embodiment, the stepping gear is configured such that at least one of the die bonding pens arrive at the chip pickup position or the die bonding position at each step. That is, the stepping gear and the transmission chain may be properly configured such that one die bonding pen arrives at a position where its preceding die bonding pen was located at each step forward. As such, after the preceding die bonding pen leaves, the next die bonding pen may be in place at one step. For example, in an embodiment, a die bonding pen may be disposed on each pitch point of the transmission chain, and the die bonding pen advances a distance of one chain element at each step. As such, at each step of the stepping gear, each die bonding pen will advance one step on the transmission chain loop to arrive at the position where the preceding die bonding pen was located.

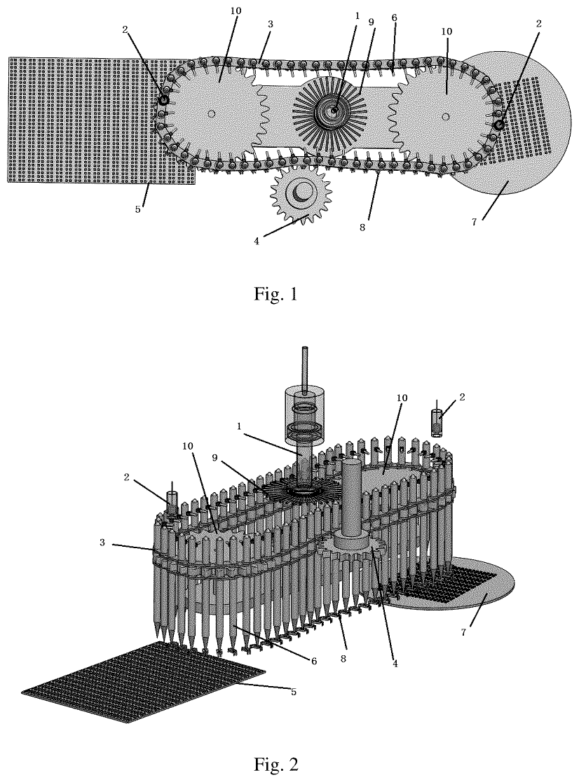

FIG. 1 shows a top view of an embodiment of a chain-type die bonding device according to the present disclosure. FIG. 2 shows a perspective view of the embodiment of FIG. 1. Here, a transmission chain loop 3 is disposed in a horizontal plane, and is provided with a vertically disposed die bonding pen 6 at each pin (pitch point). Two stepping gears 10 are provided inside the transmission chain loop 3 and cooperate with it. A tensioning gear 4 is provided outside the transmission chain loop 3 to maintain the transmission chain loop 3 tensioned. As such, when the stepping gears 10 rotate step by step, they drive the transmission chain loop 3 to advance step by step so as to drive the die bonding pens 6 to advance accordingly. In an embodiment, at each step of the stepping gears 10, the transmission chain loop 3 advances a distance of one chain element, such that one die bonding pen 6 arrives at the position where its adjacent preceding die bonding pen was located.

In FIG. 1 and FIG. 2, an initial substrate 7 on which a chip array is arranged is located on the right side, and a target substrate 5 provided with positions for mounting chips is located on the left side. A chip pickup position and a die bonding position (each located vertically below die bonding pen positioners 2) are provided within the initial substrate 7 and the target substrate 5 respectively, and the die bonding pen 6 arriving at those two positions may perform a chip pickup action and a die bonding action respectively. Subsequently, the stepping gears 10 rotate one step clockwise. The die bonding pen 6, which has completed the chip pickup action and carries a chip 8, leaves the chip pickup position, and begins to move towards the die bonding position along the lower half of the transmission chain loop in FIG. 1. The die bonding pen 6, which has completed the die bonding action and is vacant, leaves the die bonding position, and begins to move towards the chip pickup position along the upper half of the transmission chain loop in FIG. 1. Meanwhile, the next vacant die bonding pen 6 in a queuing state arrives at the chip pickup position, and the next die bonding pen 6 carrying a chip 8 in a queuing state arrives at the die bonding position. The figures also show a rotatable negative pressure gas cylinder 1, which is provided with a plurality of radially extending pipeline connection ports 9 for communicating with the pipeline connectors of the die bonding pens 6 via pipelines (such as flexible pipelines, not shown).

Because a chip corresponding to the chip pickup position on the initial substrate has been taken away, and a chip has been mount at the position corresponding to the die bonding position on the target substrate, the stages supporting the initial substrate 7 and the target substrate 5 have been translated, and a new chip and a target substrate without any chip mounted are provided respectively for the chip pickup position and the die bonding position. The support stage with such a function is known in the related technologies. For example, an automated optical inspection (AOI) machine may be used to assist the positioning of the support stage at the chip pickup position and the die bonding position.

By using the steps as described above, the chain-type die bonding device of the present disclosure picks up a chip from the initial substrate, transfers the chip along the transmission chain loop step by step to the target substrate, and mounts the chip onto the target substrate. As compared to the swing-arm-type die bonder, this may greatly reduce the tact time and the cycle time, thereby greatly increasing the overall speed for the die bonding, improving the die bonding efficiency, and increasing the production capacity.

The chip as well as corresponding initial substrate and target substrate may be objects involved in the die bonding related technologies, such as LED chips, discrete devices, and wafers. The chip pickup and die bonding may be carried out by a conventional process in the related technologies. For example, the chip pickup may be done through a suction nozzle, and the die bonding may be done through welding. The solder used in welding may be a soldering tin. For example, a solder paste may be provided at a site for die bonding on the target substrate, and then a chip is placed thereon to carry out die bonding.

The number and position of the die bonding pens disposed on the transmission chain loop may be properly configured. As shown in FIG. 1 and FIG. 2, a die bonding pen may be provided at each pitch point of the transmission chain. Nevertheless, a die bonding pen may also be provided only at some pitch points selected therefrom. The die bonding pen may also be provided at a position other than the pitch points, as long as it is disposed with respect to the transmission chain loop and may move to a fixed position step by step with the stepping of the transmission chain.

The shape of the transmission chain loop may be properly configured depending on particular requirements, and may be adjusted by adding more stepping gears or tensioning gears. As shown in FIG. 1 and FIG. 2, the transmission chain loop 3 may have a segment protruding outward, and may also have a segment recessed inward. The tensioning gear 4 makes the transmission chain loop 3 have an appropriate degree of tensioning.

The relative relationship between the stepping magnitude of the stepping gear and the stepping magnitude of the transmission chain may be properly adjusted, such that the die bonding pen will be in place after an appropriate stepping number. As described above, it is preferable that the stepping gear may make one die bonding pen in place at each step. Nevertheless, the stepping gear may also make one die bonding pen in place after several steps.

In order to further increase the positioning accuracy of the die bonding pen, in an embodiment, the chip pickup position and the die bonding position are provided with die bonding pen positioners. FIG. 1 and FIG. 2 show the die bonding pen positioners 2 located at the chip pickup position and the die bonding position.

The die bonding pen positioners are used for positioning the die bonding pen more accurately. Because the transmission chain may be slightly relaxed, the spatial position of the die bonding pen may be further limited for more accurate positioning. The die bonding pen positioners are disposed at the chip pickup position and the die bonding position independently from the transmission chain, and may impose a removable spatial limit on the die bonding pen moving to those positions, such that the die bonding pen carries out a chip pickup action or a die bonding action at desirable accurate horizontal and vertical coordinates, and is released from the die bonding pen positioner after completing the action. In an embodiment, the die bonding pen positioner may only move vertically, such that the die bonding pen temporarily fixed thereon may be pressed down and lifted up in the vertical direction, but fixed in position in the horizontal direction.

In an embodiment, an AOI may also be used to assist positioning. Various AOIs may be used to move the stage supporting the initial substrate or the target substrate and then make accurate alignment at the chip pickup position or the die bonding position. Any suitable AOI in the related technologies may be used. Preferably, the AOI-assisted positioning of the support stage cooperates with the positioning of the die bonding pen positioner, such that the die bonding pen can be more accurately aligned with the desired position on the initial substrate or the target substrate, thereby achieving extremely accurate chip pickup and die bonding. Such a process may be referred to as position correction. That is, the initial substrate or the target substrate can be more accurately moved to the chip pickup position and the die bonding position through AOI.

Because a free shape transmission chain loop design is used in the present disclosure, there is great flexibility in the design for the chip pickup position and the die bonding position in the chain-type die bonding device of the present disclosure may be very flexible, as compared to the swing-arm-type die bonding device where the chip pickup position and the die bonding position may only be arranged on the arc where the robot arm is located. The shape of the transmission chain loop may be predetermined, and then the stages supporting the initial substrate and the target substrate may be disposed to cooperate with that shape.

Furthermore, the chip pickup action and the die bonding action of the present disclosure may be completed simultaneously. As compared to the swing-arm-type die bonding device where chip pickup and die bonding are typically carried out alternately, the chain-type die bonding device of the present disclosure may further save time, thereby increasing the efficiency.

In an embodiment, the transmission chain loop passes through a group of die bonding positions located on a straight line, and a distance between two adjacent die bonding positions of the group of die bonding positions is equal to a distance between adjacent die bonding pens.

In the present disclosure, “a group” of chip pickup positions or die bonding positions refers to a plurality of positions for the same initial substrate or target substrate.

In this embodiment, the chain-type die bonding device of the present disclosure may pick up a chip from any chip pickup position, and carry out die bonding at a group of die bonding positions on a target substrate simultaneously. This embodiment may quickly mount a plurality of chips of the same type or different types onto the target substrate in groups.

For example, those with the same color of the sub-pixels are periodically arranged on the display substrate. Therefore, it may be desirable to periodically mount the light-emitting chips of a plurality of sub-pixels with the same color onto the target substrate at one time. In this case, a group of continuous die bonding heads may pick up those sub-pixels with the same color, and simultaneously mount those sub-pixels with the same color on a straight line (which may also be referred to as a first straight line) on the target substrate at one time. The spacing between the sub-pixels with the same color as formed, i.e., the spacing between adjacent die bonding heads, is an integer multiple of the spacing between the sub-pixels of that color of adjacent pixel units in the display device. The display substrate may be efficiently formed by sequentially mounting the light-emitting chips of the same color in batches according to different colors in this way.

Also, for example, in the case where it is desirable to mount R/G/B LEDs onto the target substrate to form RGB pixels, it may be considered to use the following process to carry out chip pickup and die bonding. The transmission chain loop sequentially passes through an initial substrate providing red LEDs, an initial substrate providing green LEDs, and an initial substrate providing blue LEDs. As the transmission chain advances, three adjacent vacant die bonding heads on the transmission chain loop first pass through the initial substrate providing red LEDs, and one of the die bonding heads picks up a red LED at the chip pickup position of the initial substrate. Subsequently, when passing through the initial substrate providing green LEDs, one of the remaining two vacant die bonding heads picks up a green LED at the chip pickup position of the initial substrate. Finally, when passing through the initial substrate providing blue LEDs, the remaining vacant die bonding head picks up a blue LED at the chip pickup position of the initial substrate. Thus, three adjacent die bonding heads respectively picking up red, green and blue LEDs are obtained. When those three die bonding heads arrive at the die bonding positions on a straight line on the target substrate, because the distance between two adjacent die bonding positions is equal to the distance between adjacent die bonding pens, red, green and blue LEDs may be mounted onto the target substrate simultaneously, thereby significantly saving time as compared to separately mounting single color LEDs. The embodiment where several different chips are quickly mounted onto the target substrate in groups may further increase the overall speed, and mounting in groups may also increase the relative accuracy between the mounted chips.

It is a unique capability of the chain-type die bonding device of the present disclosure to mount a plurality of chips in groups at the die bonding positions on a straight line simultaneously, because the shape of the transmission chain loop may be arbitrarily designed and a straight line segment may be formed. Instead, in the swing-arm-type die bonding device, because the route of the die bonding head is an arc, it is not possible to mount a plurality of chips on a straight line simultaneously.

In another embodiment, the transmission chain loop passes through a group of chip pickup positions located on a straight line (which may also be referred to as a second straight line), and a distance between two adjacent chip pickup positions of the group of chip pickup positions is equal to a distance between adjacent die bonding pens.

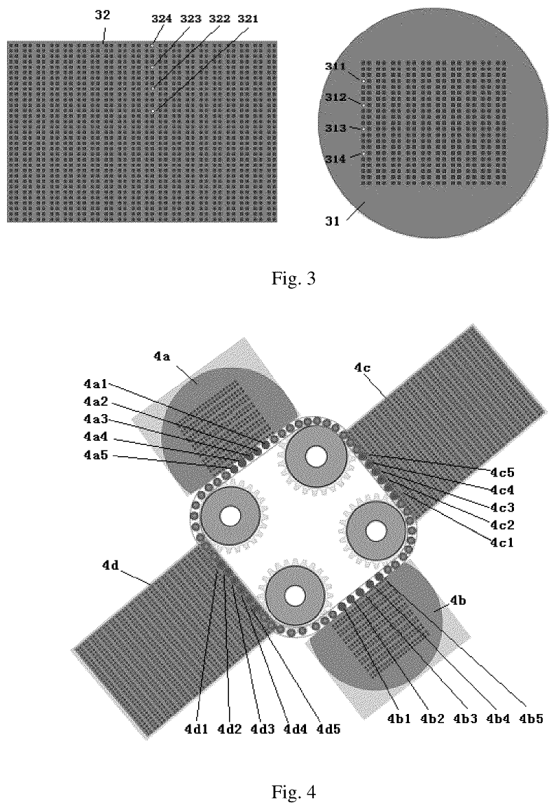

In this embodiment, the chain-type die bonding device of the present disclosure may carry out chip pickup and die bonding in groups. A plurality of chips may be picked up in groups at adjacent chip pickup positions on a straight line by configuring the transmission chain loop to have a straight line segment at an initial substrate, thereby further saving time and increasing the overall speed. This is particularly beneficial when transferring and mounting chips array to array on a large scale. In view of the larger spacing between the die bonding heads on the transmission chain than the spacing between the LEDs arranged on the initial substrate, the spacing between the LEDs arranged on the initial substrate may be configured to be 1/n (where n is an integer) of the spacing between two adjacent die bonding heads, thereby facilitating chip pickup. Accordingly, the spacing between the sites for die bonding on the target substrate may also be configured to be 1/n (where n is an integer) of the spacing between two adjacent die bonding heads. FIG. 3 schematically shows a schematic diagram of a chip and a corresponding arrangement of sites for die bonding. Here, the right figure represents a circular initial substrate 31 and chips arranged in a rectangular array on the initial substrate 31, and the left figure represents a rectangular target substrate 32 and sites for die bonding arranged in a rectangular array on the target substrate 32. Chips 311, 312, 313, 314 in white color represent chips corresponding to a group of chip pickup positions. The spacing between the chip pickup positions and the spacing between the chips in the chip array on the initial substrate are configured such that the spacing between the chip pickup positions is four times the spacing between the chips. As such, the chips 311-314 may be aligned with the group of four chip pickup positions by moving the initial substrate. The spacing between the die bonding heads is also configured to be the spacing between the chip pickup positions, such that those four die bonding heads may be aligned with those chip pickup positions simultaneously and pick up those chips at one time. Accordingly, the spacing between the sites for die bonding on the target substrate is also configured to be the same as the spacing between the chip pickup positions, thereby facilitating die bonding. For example, the chips 311-314 may be respectively mounted at the sites for die bonding 321, 322, 323, and 324 in white color simultaneously. It should be noted that the figures only show an example part.

In an embodiment, the transmission chain loop passes through a plurality of groups of the chip pickup positions and a plurality of groups of the die bonding positions. The combination of the chip pickup position and the die bonding position may be flexibly configured to achieve chip pickup from a plurality of initial substrates and die bonding onto a plurality of target substrates.

As an example, FIG. 4 shows a schematic diagram of an embodiment in which two groups of chip pickup positions and two groups of die bonding positions are provided. A substantially rectangular transmission chain loop having four straight sides is formed by providing four stepping gears. Two initial substrates 4a, 4b and two target substrates 4c, 4d, are alternately provided on the four straight sides respectively, forming two groups of chip pickup positions (4a1, 4a2, 4a3, 4a4, 4a5) and (4b1, 4b2, 4b3, 4b4, 4b5) and two groups of die bonding positions (4c1, 4c2, 4c3, 4c4, 4c5) and (4d1, 4d2, 4d3, 4d4, 4d5) accordingly, wherein the chip pickup positions and the die bonding positions in the same group are located on a straight line. As such, the same transmission chain loop may be used to simultaneously process two pieces of target substrates, thereby increasing the die bonding efficiency and the production.

Because of the flexibility in the shape of the transmission chain loop, in the chain-type die bonding device of the present disclosure, the initial substrates and the target substrates may be properly arranged as needed, thereby fully increasing the overall speed and the production efficiency.

In an embodiment, the chain-type die bonding device further comprises a rotatable negative pressure gas cylinder having an internal cavity in gas communication with the die bonding heads via a pipeline, wherein the rotatable negative pressure gas cylinder may be supported on the support surface through a ring-shaped ball bearing, and may be rotated on the support surface by movement of the die bonding pens via the flexible air pipe. The pipeline may be, for example, a flexible air pipe, a partially flexible air pipe, or the like.

In the swing-arm-type die bonding device, the die bonding head will move at a relatively high speed along a circular path around an axis at a fixed radius. Therefore, the die bonding head is generally in communication with a negative pressure air pipe provided around the rotation axis through a fixed gas path which extends along the robot arm and moves together with the robot arm. In contrast, when the chain-type die bonding device of the present disclosure operates, the positions of the plurality of die bonding pens therein move along the transmission chain loop, and the transmission chain loop is generally not circular and thus does not have an axis at the center of a circle. Furthermore, the chain-type die bonding device of the present disclosure does not have a fixed-length robot arm either. Therefore, the fixed gas path which extends along the robot arm and moves together with the robot arm is not suitable for the chain-type die bonding device of the present disclosure.

In an embodiment, for the chain transmission process, negative pressure may be conveniently provided to the plurality of die bonding pens with continuously changing positions along the transmission chain loop by using a rotatable negative pressure gas cylinder. The rotatable negative pressure gas cylinder is supported on the support surface through a ring-shaped ball bearing, and may rotate on the support surface. The support surface is used to support the ring-shaped ball bearing. In order to allow the rotatable negative pressure gas cylinder to rotate, necessary constraints are imposed on the ring-shaped ball bearing in the plane direction along the support surface. In an embodiment, the support surface is substantially a horizontal plane, and ideally is completely a horizontal plane. In this case, the rotatable negative pressure gas cylinder supported thereon may rotate about a vertical rotation axis, and the ring-shaped ball bearing may be a main force-bearing position for supporting the dead weight of the rotatable negative pressure gas cylinder.

The rotatable negative pressure gas cylinder is used to provide negative pressure to the die bonding pens, such that the die bonding pens may pick up chips with the negative pressure. The rotatable negative pressure gas cylinder has an internal cavity, wherein the internal cavity is in gas communication with a negative pressure air pipe which is further connected with a negative pressure source, and is in gas communication with the die bonding pens via a flexible gas pipe. As such, the negative pressure from the negative pressure air pipe may be applied to the die bonding pens via the internal cavity of the rotatable negative pressure gas cylinder and the flexible gas pipe. Because of the use of the flexible gas pipe, the distance between the die bonding pens and the rotatable negative pressure gas cylinder is variable. In an embodiment, the flexible gas pipe has a length not less than the greatest distance between the rotatable negative pressure gas cylinder and the transmission chain loop. As such, it may be ensured that the rotatable negative pressure gas cylinder achieves a negative pressure supply to a die bonding pen at any position on the transmission chain loop.

The rotatable negative pressure gas cylinder used in the present disclosure is characterized in that it may be passively rotated along with the movement of the die bonding pens. That is, instead of using a special driving device to actively rotate the rotatable negative pressure gas cylinder, the rotatable negative pressure gas cylinder may be rotated on the support surface by movement of the die bonding pens via the flexible gas pipe. Specifically, when a die bonding pen advances step by step along with the chain transmission loop, the connection point of the flexible gas pipe connected therewith on the rotatable negative pressure gas cylinder may not move temporarily, because the flexible gas pipe is flexible and may have a length greater than the distance between the die bonding pen and the connection point. When the die bonding pens continue to advance, the distance between the die bonding pen and the above connection point may increase, such that the flexible gas pipe may be gradually straightened. If the flexible gas pipe is straightened to such an extent that the connection point is under stress, it will apply a force to the rotatable negative pressure gas cylinder. Because of the presence of the ring-shaped ball bearing, the horizontal component of this pulling force, even very slight, will cause the rotatable negative pressure gas cylinder to rotate. With the rotation of the negative pressure gas cylinder, the connection point becomes closer to the advancing die bonding pen, and thus the distance from the die bonding pen may be reduced, such that the flexible gas pipe is relaxed, the connection point is no longer under stress, and the rotatable negative pressure gas cylinder may stop rotating. Such a process is repeated, such that the rotatable negative pressure gas cylinder may cooperate with the movement of the die bonding pen to rotate, thereby ensuring a good connection of the flexible gas pipe between the die bonding pen and the rotatable negative pressure gas cylinder and a good negative pressure delivery to the die bonding pen. It should be understood that the rotation of the rotatable negative pressure gas cylinder is an overall result of the movement of the die bonding pen and the flexible gas pipe.

The passively rotated rotatable negative pressure gas cylinder brings about many advantages to the chain-type die bonding device of the present disclosure. Because the negative pressure air pipe is in gas communication with the die bonding pen through the rotatable negative pressure gas cylinder via the flexible gas pipe, the distance between the die bonding pen and the negative pressure air pipe for providing negative pressure may be flexible. Because it is passively rotated, it may be self-adapted to various positions of the die bonding pens without any accurate adjustment. Furthermore, it is not necessary to additionally provide an active driving device for the rotation of the negative pressure gas cylinder, thereby reducing the equipment investment. Also, because of the use of the ball bearing, very small driving force is needed, so excess power may be fully utilized, and there is no need for the stepping gear and the transmission chain loop to provide additional energy to the die bonding pens and the flexible gas pipe.

In a more specific embodiment, the chain-type die bonding device further comprises:
a fixed cylinder, wherein the fixed cylinder has an internal cavity in gas communication with a negative pressure air pipe, and an inner wall of the fixed cylinder has an inward flange as the support surface which has a through hole at its center;
wherein the rotatable negative pressure gas cylinder is a suspended negative pressure gas cylinder passing through the through hole, the ring-shaped ball bearing is on an outer side wall of the suspended negative pressure gas cylinder and suspended on the flange, the internal cavity of the suspended negative pressure gas cylinder is slidably joined to the internal cavity of the fixed cylinder and is sealed at a joint, and a side wall of the suspended negative pressure gas cylinder is provided with a plurality of flexible gas pipe connection ports.

Through the cooperation of the fixed cylinder with the rotatable negative pressure gas cylinder, the rotation of the rotatable negative pressure gas cylinder and the negative pressure supply to the die bonding pen may be conveniently achieved.

The fixed cylinder mainly has two functions. The first function is to connect the negative pressure air pipe, and the second function is to provide a support surface and horizontal constraint for the rotatable negative pressure gas cylinder.

The distal end of the relatively thick negative pressure air pipe for supplying negative pressure to the entire system is typically connected to an external negative pressure source at a fixed position. Therefore, it is desirable to connect the proximal end of the negative pressure air pipe to a fixed position, and it is more desirable to use a non-flexible negative pressure air pipe, to ensure the negative pressure delivery. Therefore, the fixed cylinder may be provided as a transition between the rotatable negative pressure gas cylinder and the negative pressure air pipe, rather than connecting the negative pressure air pipe directly to the rotating rotatable negative pressure gas cylinder.

The fixed cylinder also provides a support surface and horizontal constraint for the rotatable negative pressure gas cylinder through the flange on its inner wall and the through hole therein. Accordingly, the ring-shaped ball bearing is on the outer side wall of the rotatable negative pressure gas cylinder. As such, the rotatable negative pressure gas cylinder may be “suspended” in the fixed cylinder by disposing the ring-shaped ball bearing on the flange and simultaneously passing the rotatable negative pressure gas cylinder through the through hole. In this case, the rotatable negative pressure gas cylinder may be referred to as a suspended negative pressure gas cylinder. The suspended negative pressure gas cylinder is suspended in the fixed cylinder, and may rotate on the flange in the through hole.

The internal cavity of the suspended negative pressure gas cylinder is slidably joined to the internal cavity of the fixed cylinder and is sealed at a joint. That is, the internal cavity of the suspended negative pressure gas cylinder and the internal cavity of the fixed cylinder are joined to form a space which is not in gas communication with the outside, but relative rotational displacement may occur between the internal cavity of the suspended negative pressure gas cylinder and the internal cavity of the fixed cylinder. This may be achieved by for example providing a seal ring at a suitable position outside the joint. By such joining, the suspended negative pressure gas cylinder may get negative pressure through the internal cavity of the fixed cylinder, and the negative pressure will not leak. Meanwhile, the suspended negative pressure gas cylinder may rotate relative to the non-rotating fixed cylinder by for example sliding.

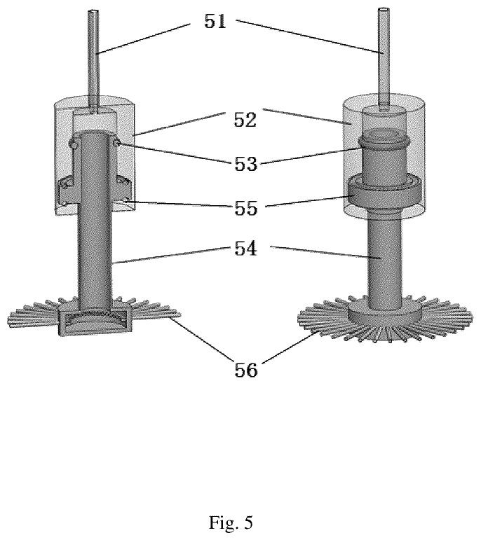

FIG. 5 shows a schematic diagram of an embodiment of a fixed cylinder and a rotatable negative pressure gas cylinder 4. Here, the internal cavity of the fixed cylinder 52 is connected with the negative pressure air pipe 51. The rotatable negative pressure gas cylinder 54 is sleeved in the fixed cylinder 52. The rotatable negative pressure gas cylinder 54 comprises a first end and a second end in communication with each other, and the second end is closer to the negative pressure air pipe 51 than the first end. That is, the rotatable negative pressure gas cylinder has a first end away from the negative pressure air pipe and a second end close to the negative pressure air pipe, and both the first end and the second end are communicated with each other through the internal cavity of the rotatable negative pressure gas cylinder. The outer side wall of the rotatable negative pressure gas cylinder 54 comprises a protrusion, the fixed cylinder 52 comprises a recess formed by inward extending of an inner wall, and the protrusion is fitted into the recess, such that the internal cavity of the rotatable negative pressure gas cylinder 54 is slidably joined to the internal cavity of the fixed cylinder 52, and is sealed at a joint with a seal ring 53. The rotatable negative pressure gas cylinder 54 has a plurality of pipeline connection ports 56 for connecting to the pipeline. Specifically, the pipeline connection ports 56 are located at the first end. The pipeline connected to the pipeline connection ports 56 may drive the rotatable negative pressure gas cylinder 54 to passively rotate in the fixed cylinder 52 when it moves along with the die bonding pens. In this process, the negative pressure air pipe 51 may continuously apply negative pressure to the pipeline connection ports 56 for picking up chips by suction with the die bonding pens. Specifically, the rotatable negative pressure gas cylinder 54 may be a suspended negative pressure gas cylinder.

For example, a ring-shaped ball bearing 55 is provided between the rotatable negative pressure gas cylinder 54 and the fixed cylinder 52, and the ring-shaped ball bearing 55 comprises a plurality of balls disposed around the rotatable negative pressure gas cylinder 54. For example, first groove structures are provided respectively on the protrusion and the recess, and the first groove structures on the protrusion and the recess are disposed to face each other to form a first sliding track for the ring-shaped ball bearing 55. That is, the recess and the protrusion have opposite grooves forming a first groove structure, and the first groove structure serves as a first sliding track to accommodate the balls to form a ball bearing. For example, there may be a plurality of ring-shaped ball bearings 55. Preferably, second groove structures are further provided respectively on the protrusion and the recess. The second groove structures on the protrusion and the recess are disposed to face each other to form a second sliding track for another ring-shaped ball bearing 55. That is, the recess and the protrusion also have opposite grooves forming a second groove structure, and the second groove structure serves as a second sliding track to accommodate the balls to form a ball bearing. Referring to FIG. 5, the first sliding track and the second sliding track are located respectively at two opposite sides of the recess formed by inward extending of the inner wall of the fixed cylinder 52. Specifically, the first sliding track and the second sliding track are located respectively at a side close to the first end and a side close to the second end of the recess. In this way, the cooperative sliding effect of the rotatable negative pressure gas cylinder 54 and the fixed cylinder 52 is better.

For example, the seal ring 53 is disposed around the rotatable negative pressure gas cylinder 54. For example, third groove structures are provided respectively on the outer side wall of the rotatable negative pressure gas cylinder 4 and the inner wall of the fixed cylinder 52. Specifically, opposite grooves forming the third groove structure are provided respectively on the outer side wall of the rotatable negative pressure gas cylinder 54 and the inner wall of the fixed cylinder 52; and the third groove structure is disposed around the rotation axis of the rotatable negative pressure gas cylinder 54. The seal ring 53 is located in the third groove structure. That is, the third groove structure accommodates the seal ring surrounding the rotatable negative pressure gas cylinder. Preferably, the seal ring 53 is filled into the third groove structure on the outer side wall of the rotatable negative pressure gas cylinder 54 and the inner wall of the fixed cylinder 52. In this way, the sealing effect is better.

For example, the seal ring 53 is disposed close to the second end.

For example, the seal ring 53 is located on a side of the protrusion away from the pipeline connection ports 56. That is, the seal ring 53 is further away from the protrusion than the first end.

For example, the rotatable negative pressure gas cylinder 54 may be a suspended negative pressure gas cylinder. The negative pressure air pipe 51, the fixed cylinder 52 and the suspended negative pressure gas cylinder are disposed sequentially in a direction gradually approaching the ground, such that the suspended negative pressure gas cylinder is suspended on the fixed cylinder 52. Specifically, the negative pressure air pipe 51, the seal ring 53, the protrusion and the pipeline connection ports 56 are disposed sequentially in the direction gradually approaching the ground, such that the suspended negative pressure gas cylinder is passively rotated.

For example, the pipeline connection ports 56 are disposed around the rotation axis of the rotatable negative pressure gas cylinder 54. In this way, the pipelines may drive the rotatable negative pressure gas cylinder 54 to rotate effectively. For example, the distribution plane of the plurality of pipeline connection ports 56 is perpendicular to the rotation axis of the rotatable negative pressure gas cylinder 54, and the plurality of pipeline connection ports 56 may be evenly arranged along the circumference.

It should be understood that the above combination of the fixed cylinder and the suspended negative pressure gas cylinder is only an example embodiment for the rotatable negative pressure gas cylinder. Components with other specific shapes and structures may be used to achieve the aforementioned rotatable negative pressure gas cylinder.

In an embodiment, the chain-type die bonding device of the present disclosure further comprises an electromagnetic die bonding pen positioner, wherein
the electromagnetic die bonding pen positioner has an electromagnetic attracting component, and
the die bonding pen has a permanent magnetic component, such that when the permanent magnetic component is attracted by the electromagnetic attracting component, the die bonding pen is temporarily fixed to the electromagnetic die bonding pen positioner.

There may be a problem in high positioning accuracy when the transmission chain loop is used to transfer the die bonding pen. The transmission chain may have slightly less position stability than the robot arm. Therefore, although the die bonding pen may perform the chip pickup action and the die bonding action directly at the chip pickup position and the die bonding position of the transmission chain loop, it is preferable to further fix the position of the die bonding pen before performing the chip pickup action and the die bonding action.

As described above, in an embodiment, the die bonding pen positioner having a fixed position may be used to position the die bonding pen, so as to provide a more accurate positioning than that provided by the transmission chain. In an embodiment of the present disclosure, the die bonding pen positioner is an electromagnetic die bonding pen positioner which utilizes an electromagnetic interaction to achieve the positioning.

In an embodiment, the chain-type die bonding device of the present disclosure further comprises an electromagnetic die bonding pen positioner, wherein
the electromagnetic die bonding pen positioner has an electromagnetic attracting component, and the die bonding pen comprises a permanent magnetic component or comprises a metal (such as iron, cobalt and nickel) capable of being attracted by a magnet, such that when the permanent magnetic component is attracted by the electromagnetic attracting component, the die bonding pen is temporarily fixed to the electromagnetic die bonding pen positioner.

The electromagnetic die bonding pen positioner has advantages of high speed, easy control and low cost. By providing the electromagnetic attracting component in the positioner to cooperate with the permanent magnetic component or the metal capable of being attracted by a magnet in the die bonding pen, the die bonding pen may be fixed and released rapidly.

As such, when the die bonding pen is transferred to the chip pickup position or the die bonding position along with the transmission chain, the electromagnetic attracting component is powered to attract the die bonding pen and fix it to an accurate chip pickup position or die bonding position. It should be understood that the displacement of the die bonding pen required for achieving accurate positioning is slight, and its overall position is still provided by the transmission chain. In an embodiment, as described below, the die bonding pen may be composed of a fixed part and a movable part. The fixed part may be for example a tubular pen cylinder, and the movable part may be for example a columnar pen core. The tubular pen cylinder has a fixed position with respect to the transmission chain loop, and the columnar pen core with a suction nozzle can slightly displace horizontally and vertically relative to the tubular pen cylinder. As such, further fine tuning of the position of the suction nozzle may be achieved when the die bonding pen is substantially positioned by the transmission chain.

In a preferred embodiment, the electromagnetic die bonding pen positioner has a concave bottom, and the die bonding pen has a convex top, such that when the die bonding pen is attracted by the electromagnetic attracting component, an outer surface of the convex top is adjacent to an inner surface of the concave bottom. For example, preferably, the concave bottom and the convex top both have a circular truncated cone-shaped structure.

In a preferred embodiment, the electromagnetic die bonding pen positioner has a convex bottom, and the die bonding pen has a concave top, such that when the die bonding pen is attracted by the electromagnetic attracting component, an outer surface of the convex bottom is adjacent to an inner surface of the concave top. For example, preferably, the concave top and the convex bottom both have a circular truncated cone-shaped structure.

When the die bonding pen moves below such a concave-convex magnetic mechanism (an electromagnetic die bonding pen positioner), the magnetic system starts to attract the convex structure to the inside of the concave structure. The cooperation of the adjacent convex structure and concave structure may effectively use electromagnetic attraction to smoothly guide the die bonding pen to the positioned site, and may allow the die bonding pen to easily exit the positioner after the electromagnetic attraction disappears. Also, the cooperation of the convex surface and the concave surface, especially the cooperation of the circular truncated cone-shaped convex surface and concave surface, may achieve an extremely high accuracy. The inventors have found that the use of such an electromagnetic die bonding pen positioner in the chain-type die bonding device of the present disclosure further ensures the die bonding accuracy, thereby improving the yield, and the positioning process is fast and easy to control.

Typically, the negative pressure provided to the die bonding pen is constant. For example, the negative pressure may be provided by the aforementioned rotatable negative pressure gas cylinder. Therefore, in order to pick up the chips by suction in chip pickup and put down the chips in die bonding, it is necessary to control the negative pressure at the suction nozzle (i.e., the pen tip) of the die bonding pen.

In an embodiment, the die bonding pen has a suction nozzle and an air extraction port, the suction nozzle is in gas communication with the air extraction port through the channel in the die bonding pen to form a gas path, and a controllable switch is provided in the gas path. The action of the controllable switch may be controlled by any suitable process, preferably by using a wireless process, because the die bonding pen will continuously change positions along the transmission chain loop.

In a preferred embodiment, the chip is a Mini LED or Micro LED chip for direct display. With development of the Mini LED and Micro LED towards high definition and high resolution, in the production process, the number of LED chips and ICs needed to be mounted on a single display screen is multiplied accordingly. This multiplies the manufacture time of a single display screen, and the requirement on the die bonding accuracy is also multiplied. At present, the process that limits the production capacity and yield of the Mini LED and Micro LED mainly lies in its die bonding device. In the related technologies, conventional die bonding processes comprise needling-type die bonding and swing-arm-type die bonding. Although the needling-type die bonder is efficient, it can be used only for small size LEDs when being used in the technical field of LED, and a phenomenon of missing bonding will occur. Particularly, it cannot be used in a simple solder paste welding process, so it is very limited in the LED field. Although the swing-arm-type die bonder is suitable for a solder paste welding process and may be used for large size target substrates, because the above-mentioned problem of long travel distance of the swing robot arm to pick up and put down chips results in low die bonding efficiency, it is difficult to satisfy the requirements on speed and accuracy for the Mini LED and Micro LED. In contrast, the design for the chip transfer device of the present disclosure not only increases the efficiency, but also takes both the small size and large size LEDs into account, and is not limited by the solder paste process. Therefore, when the chip transfer device of the present disclosure is used in the LED field, especially in the Mini LED and Micro LED field, it may greatly increase the production capacity, maintain a relatively high yield, and effectively improve the problems of mass production output, accuracy and quality, thereby reducing the unit cost of the product and increasing the competitiveness of the product.

When using the chain-type LED chip transfer device of the present disclosure, the initial substrate may be an organic plastic film supporting Mini LEDs and Micro LEDs arranged in an array by chip arrangement, and the target substrate may be a PCB substrate or a glass substrate.

In general, the embodiments of the chain-type die bonding device of the present disclosure may at least achieve some of the following advantages. With respect to increasing the die bonding efficiency, the overall efficiency is increased by using the transmission chain loop and the stepping gear. By using the arrangement of the die bonding heads in an array, LEDs or ICs are transferred to the positions of the target substrate one by one. Because they get closer and closer to the final die bonding position, and the path needed to be travelled becomes shorter, the efficiency and speed of die bonding are increased, and the tact time and the cycle time are reduced, thereby increasing the overall efficiency. With respect to improvement in die bonding accuracy and yield, the accuracy of the chain transmission may be further increased through the position correction with an AOI and the structure design for the concave-convex surface cooperation between the magnetic mechanism of the positioner and the die bonding head. When the die bonding head moves below the concave-convex magnetic mechanism, the magnetic system starts to attract the convex structure to the inside of the concave structure, thereby ensuring the die bonding accuracy and increasing the yield. Because of improvements in die bonding efficiency, accuracy and yield, the factory operation is more stable. Thus, the mass production plan of the factory is allowed to be carried out more stably. In the LED industry, the design for the chain-type die bonding device of the present disclosure not only increases the efficiency, but also takes into account both the small size and large size LEDs, and is not likely to be limited by the solder paste process, thereby effectively improving the problems of mass production output, accuracy and quality. The unit cost of the product is reduced, and the competitiveness of the product is increased.

In an embodiment, the present disclosure provides a method for picking up a chip in a chip pickup-die bonding process, comprising:
driving a transmission chain loop passing through a chip pickup position by a driving gear, especially a stepping gear, such that a plurality of die bonding pens fixed on the transmission chain loop sequentially arrive at the chip pickup position and pick up chips at the chip pickup position.

As described above, with the cooperative movement of the stepping gear, the transmission chain loop and the plurality of die bonding pens, and through a “queuing” mechanism, the problem of low overall speed of the method using a swing-arm-type die bonding device may be at least partially solved.

In an embodiment, the transmission chain loop passes through a group of chip pickup positions located on a straight line, and a distance between two adjacent chip pickup positions of the group of chip pickup positions is equal to a distance between adjacent die bonding pens,
wherein chips are simultaneously picked up at the group of chip pickup positions.

As described above, because of the use of a transmission chain, the method of the present disclosure may achieve simultaneous chip pickup at continuous chip pickup positions on a straight line. As such, a plurality of chips may be simultaneously picked up from one initial substrate. This cannot be achieved by the swing-arm-type chip pickup-die bonding process in which the trajectory of the die bonding head is an arc, and thus the chip pickup efficiency may be greatly increased.

In an embodiment, the method comprises: fixing a position of the die bonding pen with a die bonding pen positioner after the die bonding pen arrives at the chip pickup position;
controlling a stage supporting the initial substrate with an automated optical inspection machine, such that the chip on the initial substrate is aligned with the position of the die bonding pen; and
picking up the chip by suction to the suction nozzle by opening a gas path in the die bonding pen connecting the suction nozzle and the air extraction port for chip pickup.

In this embodiment, it is preferable to further combine the die bonding pen positioner, the automated optical inspection machine and the suction chip pickup method. As described above, the die bonding pen positioner cooperates with the proper flexibility in deformation of the transmission chain to achieve more accurate positioning. The die bonding pen positioner is preferably an electromagnetic die bonding pen positioner. Controlling and fine tuning the stage supporting the initial substrate with the AOI may allow the chip pickup of the present disclosure to achieve extremely high accuracy, and may be beneficial for subsequent die bonding. The suction-type chip pickup method is suitable for the design of the die bonding pen in a pen form, so as to achieve the pickup and subsequent putting down of a chip.

In an embodiment, the present disclosure provides a method for die bonding in a chip pickup-die bonding process, comprising:
driving a transmission chain loop passing through a die bonding position by a driving gear, especially a stepping gear, such that a plurality of die bonding pens fixed on the transmission chain loop sequentially arrive at the die bonding position and mounting chips at the die bonding position.

The die bonding may be carried out by contacting the chip with a solder paste and removing or reducing the negative pressure at the suction nozzle. The solder paste has a certain viscosity. After the chip is contacted with the solder paste and the negative pressure at the suction nozzle is removed or reduced, the viscosity is sufficient to remove the chip from the suction nozzle and position it. Because there is generally not a completely airtight seal between the drawn chip and the suction nozzle, the negative pressure at the suction nozzle may disappear quickly and naturally after cutting off the negative pressure. Of course, an additional device may also be provided for assisting the reduction of the negative pressure. For example, a valve in communication with the atmosphere may be provided in the gas path, and the valve is opened after cutting off the negative pressure.

The die bonding (or chip placement) may be considered completed after fixing the position of the chip. Nevertheless, the die bonding may also comprise a permanent fixing step such as welding. Any process of fixing a chip in the related technologies may be used.

As described above, with the cooperative movement of the driving gear, the transmission chain loop and the plurality of die bonding pens, and through a “queuing” mechanism, the problem of low overall speed of the method using a swing-arm-type die bonding device may be at least partially solved.

In an embodiment, the transmission chain loop passes through a group of die bonding positions located on a straight line, and a distance between two adjacent die bonding positions of the group of die bonding positions is equal to a distance between adjacent die bonding pens,
wherein die bonding are carried out simultaneously at the group of die bonding positions.

As described above, because of the use of a transmission chain, the method of the present disclosure may achieve simultaneous die bonding at continuous die bonding positions on a straight line. As such, a plurality of chips may be simultaneously mounted on one target substrate. This cannot be achieved by the swing-arm-type chip pickup-die bonding process in which the trajectory of the die bonding head is an arc, and thus the die bonding efficiency may be greatly increased.

Particularly in the LED field, for example, red, green, blue (RGB) LED chips may also be mounted together in groups to advantageously form a pixel element with very high chip spacing accuracy.

In an embodiment, the method comprises: fixing a position of the die bonding pen with a die bonding pen positioner after the die bonding pen arrives at the die bonding position;
controlling a stage supporting the target substrate with an automated optical inspection machine, such that the site for die bonding on the target substrate is aligned with the position of the die bonding pen; and
putting down the chip from the suction nozzle by closing a gas path in the die bonding pen connecting the suction nozzle and the air extraction port for die bonding.

In this embodiment, it is preferable to further combine the die bonding pen positioner, the automated optical inspection machine and the suction chip pickup method. As described above, the die bonding pen positioner cooperates with the transmission chain and the die bonding pen to achieve more accurate positioning. The die bonding pen positioner is preferably an electromagnetic die bonding pen positioner. Controlling and fine tuning the stage supporting the target substrate with the AOI may allow the die bonding of the present disclosure to achieve extremely high accuracy. The suction-type chip pickup method is suitable for the design of the die bonding pen in a pen form, so as to achieve the pickup and subsequent putting down of a chip.

The chip pickup method and the die bonding method of the present disclosure may be flexibly combined with each other. In an embodiment, a single chip may be picked up, and may be mounted. In an embodiment, a plurality of chips of different types may be picked up, and may be mounted in groups. In an embodiment, chips of the same type may be picked up in groups, and may be mounted in groups. In an embodiment, different chips may be picked up from a plurality of initial substrates, and may be separately mounted onto different target substrates. In an embodiment, chip pickup and die bonding may be carried out simultaneously. Parameters such as chip pickup positions, die bonding positions, chip type, and timing of chip pickup/die bonding may be further flexibly combined with each other by those skilled in the art to obtain a higher overall efficiency.

In an embodiment, the present disclosure provides a magnetic die bonding pen comprising:
a tubular pen cylinder, and
a columnar pen core in the tubular pen cylinder, the columnar pen core having a first end, a second end and a side wall extending between the first end and the second end,
wherein the columnar pen core comprises:
   a first magnetic component which is a permanent magnetic component or comprises a metal capable of being attracted by a magnet,
   a suction nozzle at the first end,
   a pipeline connector on the side wall, and
   a gas path extending inside the side wall and connecting the suction nozzle and the pipeline connector.

The magnetic die bonding pen of the present disclosure may be used in the chain-type die bonding device or chip transfer device having an electromagnetic die bonding pen positioner. The first magnetic component is a permanent magnetic component or comprises a metal capable of being attracted by a magnet, so as to cooperate with an electromagnetic pickup component positioner to achieve the positioning of the magnetic die bonding pen. The metal capable of being attracted by a magnet is, for example, iron, cobalt or nickel.

For example, the columnar pen core itself is the first magnetic component.

For example, the first magnetic component is located on a side of the columnar pen core away from the suction nozzle. The first magnetic component may be located at the second end.

By providing the electromagnetic attracting component in the positioner to cooperate with the permanent magnetic component or the metal capable of being attracted by a magnet in the die bonding pen, the die bonding pen may be fixed and released rapidly.

The function of the tubular pen cylinder is to accommodate the columnar pen core and to fix it onto the transmission chain of the chain-type die bonding device. When the tubular pen cylinder is fixed onto the transmission chain, the die bonding pen as a whole may move along with the transmission chain.

The tubular pen cylinder accommodates the columnar pen core. The function of the columnar pen core comprises achieving positioning and providing a gas path.

In an embodiment, the magnetic die bonding pen further comprises a convex structure or concave structure at the second end.

Preferably, the second end (which may be also referred to as the top, i.e., a side away from the suction nozzle at the first end, i.e., the bottom) of the columnar pen core has a convex structure or a convex contour, and may cooperate with the electromagnetic die bonding pen positioner having a concave structure or a concave contour to achieve the positioning of the columnar pen core.

Preferably, the second end of the columnar pen core has a concave structure or a concave contour, and may cooperate with the electromagnetic die bonding pen positioner having a convex structure or a convex contour to achieve the positioning of the columnar pen core.

For example, the first magnetic component is located at the top of the columnar pen core top.

In order to achieve the slight radial displacement required for positioning, the tubular pen cylinder and the columnar pen core have a clearance fit in the radial direction. The columnar pen core has a gas path inside, which connects the suction nozzle and the pipeline, so as to achieve picking up and putting down of a chip at the suction nozzle with an external negative pressure source. The aforementioned controllable switch is provided in the air pipe to control the gas path.

Preferably, the magnetic die bonding pen further comprises a restoring spring, which forms an axial connection between the tubular pen cylinder and the columnar pen core. As such, the columnar pen core may be lifted up and pressed down relative to the tubular pen cylinder under the action of the electromagnetic die bonding pen positioner and the stages supporting the initial substrate/target substrate, so as to complete actions of positioning, chip pickup and die bonding, and may be restored through the restoring spring when it leaves the chip pickup position and the die bonding position after the actions of chip pickup and die bonding are completed.

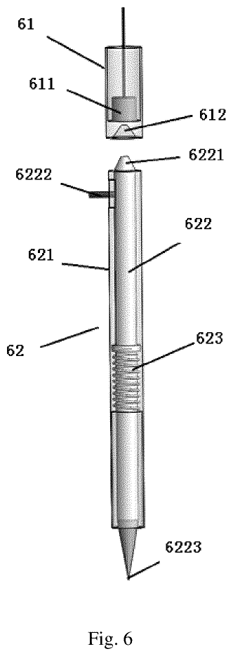

FIG. 6 shows a schematic diagram of a magnetic die bonding pen and an electromagnetic die bonding pen positioner cooperating therewith. Here, the upper electromagnetic die bonding pen positioner 61 has an electromagnet 611 as the second magnetic component and a circular truncated cone-shaped concave bottom 612, and the lower magnetic die bonding pen 62 comprises a tubular pen cylinder 621 and a columnar pen core 622 in the tubular pen cylinder 621. A restoring spring 623 is provided between the columnar pen core 622 and the tubular pen cylinder 621. The restoring spring 623 forms an axial connection between the tubular pen cylinder 621 and the columnar pen core 622. The axial connection may be achieved by fixing two ends of the restoring spring 623 respectively to the tubular pen cylinder 621 and the columnar pen core 622. For example, as shown in the figure, an upper end of the restoring spring 623 may be fixed to a flange on the outer side wall of the columnar pen core 622, and a lower end may be fixed to the inner wall of the tubular pen cylinder. The axial connection means that when the columnar pen core 622 moves upward relative to the tubular pen cylinder 621 and the restoring spring 623 is in a stretched state, the restoring spring 623 provides a gradually increasing pulling force, and generates a resistance to such a movement to form buffering; and when the columnar pen core 622 moves downward relative to the tubular pen cylinder 621 and the restoring spring 623 is in a compressed state, the restoring spring 623 provides a gradually increasing pushing force, and also generates a resistance to such a movement to form buffering. Any other fixing manner may also be used. For example, the upper end of the restoring spring is fixed to the inner wall of the tubular pen cylinder, and the lower end is fixed to the outer side wall of the columnar pen core. At this time, the restoring spring provides a gradually increasing pushing force when the columnar pen core moves upward, and the restoring spring provides a gradually increasing pulling force when the columnar pen core moves downward. Because the force provided by the restoring spring is opposite to the moving tendency, such a fixing manner may achieve buffering and restoration. In sum, the fixing manner is not particularly limited as long as the restoring spring forms an axial connection between the tubular pen cylinder and the columnar pen core.

For example, the top of the columnar pen core 622 is provided with a circular truncated cone-shaped convex top 6221 cooperating with the circular truncated cone-shaped concave bottom 612, and a first magnetic component is provided in the top 6221. Herein, the circular truncated cone may also comprise a cone. The columnar pen core 622 has a suction nozzle 6223 at the bottom, a pipeline connector 6222 on the side wall, and a gas path in communication with the suction nozzle 223 and the pipeline connector 6222 inside. A switch/valve may be provided to control the negative pressure state in the gas path. The valve may be an electromagnetic valve, such as an electromagnetic valve disposed at the pipeline connector 6222 outside the die bonding pen.

As such, the columnar pen core may move axially relative to the tubular pen cylinder, and the restoring spring provides a restorable connection between them, and provides buffering when they move relative to each other. The columnar pen core cooperates with the electromagnetic die bonding pen positioner, the AOI-controlled stages supporting the initial substrate/target substrate and the like to achieve chip pickup/die bonding actions at the chip pickup position/die bonding position. The tubular pen cylinder achieves the movement of the magnetic die bonding pen along with the transmission chain loop.

Next, it will be described with reference to FIG. 6 how the magnetic die bonding pen cooperates with the electromagnetic die bonding pen positioner to achieve chip pickup and die bonding. The columnar pen core 622 and the tubular pen cylinder 621 have a clearance fit, so even when the tubular pen cylinder 621 is fixed for example on the transmission chain, the columnar pen core 622 may slightly displace horizontally in the tubular pen cylinder 621. When the magnetic die bonding pen 62 moves below the electromagnetic die bonding pen positioner 61 at the pickup position, the electromagnetic magnet 611 of the electromagnetic die bonding pen positioner 61 is powered on, and applies a magnetic force to the first magnetic component at the top of the columnar pen core. The magnetic force overcomes the gravity of the columnar pen core 622 to pull the columnar pen core 622 upward to the magnetic die bonding pen 62. Because the circular truncated cone-shaped convex top 6221 cooperates with the circular truncated cone-shaped concave bottom 612 through a conical surface, under the magnetic force, the circular truncated cone-shaped convex top 6221 of the columnar pen core 622 will slide into the circular truncated cone-shaped concave bottom 612 of the electromagnetic die bonding pen positioner 61, and form a coaxial fixing after fitting. As such, the columnar pen core 622 loses its degree of freedom in the horizontal direction, and is accurately positioned by the magnetic die bonding pen positioner 61. In the case where the upper end of the restoring spring 623 is fixed to the flange on the outer side wall of the columnar pen core 622, and the lower end is fixed to the inner wall of the tubular pen cylinder, as shown in the figure, when the columnar pen core 622 rises and the restoring spring 623 is in a stretched state, the downward pulling force on the columnar pen core 622 provided by the restoring spring 623 gradually increases to form buffering, thereby avoiding structural damage caused by violent collision between the columnar pen core 622 and the electromagnetic die bonding pen positioner 61 or the tubular pen cylinder. The accurate horizontal positioning of the columnar pen core 622 by means of the electromagnetic die bonding pen positioner offsets the horizontal position error which may occur when the tubular pen cylinder 621 moving along with the transmission chain is in place.

When the columnar pen core 622 is closely adjacent to the magnetic die bonding pen positioner 61, the magnetic die bonding pen positioner 61 may move downward vertically to achieve chip pickup or die bonding, or in other words, chip picking up or chip placement. As the magnetic die bonding pen positioner 61 moves downward, the columnar pen core 622 moves downward in the tubular pen cylinder 621. At this time, the suction nozzle 6223 at the pen tip approaches the initial substrate or the target substrate. When picking up a chip, the suction nozzle 6223 approaches the chip on the initial substrate from above, or even comes into contact with the chip. At this time, the suction nozzle 6223 is under a negative pressure state, and the chip is picked up by suction from the initial substrate to complete the pickup action. In the case where the upper end of the restoring spring 623 is fixed to the flange on the outer side wall of the columnar pen core 622, and the lower end is fixed to the inner wall of the tubular pen cylinder, as shown in the figure, when the columnar pen core 622 descends and the restoring spring 623 is in a compressed state, the upward supporting force on the columnar pen core 622 provided by the restoring spring 623 gradually increases to form buffering, thereby avoiding structural damage caused by violent collision between the columnar pen core 622 and the electromagnetic die bonding pen positioner 61 or the tubular pen cylinder or the chip.

When the chip is drawn onto the suction nozzle 6223, the magnetic die bonding pen positioner 61 moves upward, and the electromagnetic magnet 611 is powered off. As such, the columnar pen core 622 which has picked up the chip returns to the initial position under the action of the restoring spring, and may move away from the pickup position along with the tubular pen cylinder 621.

A similar process occurs at the put-down position, except that when the magnetic die bonding pen positioner 61 is pressed down, the chip on the suction nozzle 6223 is contacted with for example a solder paste on the target substrate, and remains on the target substrate with the viscosity of the solder paste after the negative pressure of the suction nozzle 6223 is removed, thereby completing the chip placement action.

Preferably, as described above, the first magnetic component on the magnetic die bonding pen is a permanent magnet, and the second magnetic component on the magnetic die bonding pen positioner is an electromagnet. This may reduce the weight of the magnetic die bonding pen. Of course, it is also possible that the first magnetic component is configured to be an electromagnet, and the second magnetic component is configured to be a permanent magnet (or comprise a metal capable of being attracted by a magnet), or alternatively both of them are configured to be an electromagnet.

In an embodiment, as shown in FIG. 6, a side wall of the tubular pen cylinder 621 has an axially extending groove, and
the pipeline connector 6222 passes through the groove to an outside of the tubular pen cylinder.

Preferably, the pipeline connector may be perpendicular to the axis and extend radially as shown in the figure. Nevertheless, the pipeline connector may also be at an angle with respect to the axis, as long as it passes through the groove to the outside of the tubular pen cylinder.

The cooperation of the axially extending groove and the pipeline connector results in limited rotation of the pipeline connector in the horizontal direction, so as to provide a circumferential constraint for the columnar pen core 622, which may reduce its possible rotation in the tubular pen cylinder. The axially extending groove will not impede the axial relative movement between the columnar pen core and the tubular pen cylinder. Furthermore, when there is a restoring spring, the buffering provided by the restoring spring may prevent possible violent collision between the pipeline connector and both ends of the groove.

For example, when there is a restoring spring, the restoring spring makes the position of the columnar pen core 622 under the action of natural gravity (i.e., a state when it is disposed on the chain-type die bonding device and does not interact with the die bonding pen positioner) satisfy that the pipeline connector does not come into contact with the upper and lower edges (i.e., edges on two sides in the axial direction) of the axially extending groove, such that the restoring spring has a good buffering effect.

In an embodiment, an electromagnetic valve is provided at the pipeline connector outside the tubular pen cylinder. The advantage of providing the electromagnetic valve at the pipeline connector outside the tubular pen cylinder is that the electromagnetic valve is generally large, so providing it inside the columnar pen core will take up space, which is not beneficial for further miniaturize the die bonding pen.

Based on the above findings, in an aspect, the present disclosure provides a chip transfer device comprising:
a transmission chain loop passing through pickup position(s) and put-down position(s);
a driving gear cooperating with the transmission chain loop; and
a plurality of pickup components disposed on the transmission chain loop,
wherein the driving gear is configured to drive the transmission chain loop such that the pickup components arrive at the pickup positions and the put-down positions, and the pickup component is configured to pick up a chip at a pickup position and put down the chip at a put-down position.

The advantage of using the transmission chain loop to fix and move the chip pickup component at least lies in that high density and queuing mechanism of the pickup components may be achieved to increase the overall efficiency, and also the transmission chain loop may provide a flexible movement path and advantages therewith.

In an embodiment, the transmission chain loop passes through at least one group of put-down positions comprising a plurality of put-down positions on a first straight line.

The group of put-down positions configured in this way may be beneficial for simultaneously putting down a plurality of chips on a straight line.

In an embodiment, the chips includes light-emitting chips serving as sub-pixels of a display device, wherein the light-emitting chips include first light-emitting chips,
the chip transfer device is configured to transfer the first light-emitting chips from a first initial substrate to a first target substrate, such that the first light-emitting chips are periodically arranged on the first target substrate along a first direction,
the first straight line extends along the first direction, and
a distance between two adjacent put-down positions in the group of put-down positions is equal to an integer multiple of an arrangement period of the first light-emitting chips.

Such a configuration may be beneficial for periodically forming sub-pixels of the same color in a display device.

In an embodiment, the transmission chain loop passes through at least one group of pickup positions comprising a plurality of pickup positions on a second straight line.

The group of pickup positions configured in this way may be beneficial for simultaneously picking up a plurality of chips from the chips arranged in a straight line.

In an embodiment, the chip transfer device is configured to transfer the chips from a first initial substrate to a first target substrate, such that the chips are periodically arranged on the first initial substrate along a second direction,
the second straight line extends along the second direction, and
a distance between two adjacent pickup positions in the group of pickup positions is equal to an integer multiple of an arrangement period of the chips.

The group configured in this way may be beneficial for simultaneously picking up a plurality of chips from the chips arranged in a straight line. Subsequently, they may be entirely transferred to the target substrate.

In an embodiment, the chip includes light-emitting chips serving as sub-pixels of a display device, wherein the light-emitting chips include first light-emitting chips and second light-emitting chips, and the first light-emitting chips and the second light-emitting chips have different luminous colors,
the chip transfer device is configured to transfer the first light-emitting chips from a first initial substrate to a first target substrate, and transfer the second light-emitting chips from a second initial substrate to the first target substrate,
the chip transfer device comprises a first supporting area and a second supporting area, wherein the chip transfer device supports the first initial substrate in the first supporting area, and the chip transfer device supports the second initial substrate in the second supporting area,
a portion of the pickup positions are located in the first supporting area, and a portion of the pickup positions are located in the second supporting area,
the chip transfer device comprises a target-supporting area, wherein the chip transfer device supports the first target substrate in the target-supporting area, and the put-down position(s) are located in the target-supporting area, and
the transmission chain loop is configured to drive the plurality of pickup components to sequentially pass through the first supporting area, the second supporting area and the first target-supporting area.

Such a configuration may pick up different chips from different initial substrates and transfer them to the same target substrate.

In the present disclosure, the term “supporting area” refers to an area supporting an initial substrate/target substrate, which is equivalent to a range within which the initial substrate/target substrate may move.

As shown in FIG. 7, the first initial substrate I1, the second initial substrate I2 and the first target substrate T1 may be in corresponding supporting areas ZI1, ZI2, ZT3, and may be movable. Pickup positions or put-down positions may be provided in corresponding supporting areas. The transmission chain loop L passing through those positions may achieve the transfer of different kinds of chips from different initial substrates to the same target substrate.

In an embodiment, the light-emitting chips further include third light-emitting chips, wherein the first light-emitting chips, the second light-emitting chips and the third light-emitting chips have different luminous colors,
the chip transfer device is configured to further transfer the third light-emitting chips from a third initial substrate to the first target substrate,
the chip transfer device further comprises a third supporting area, wherein the chip transfer device supports the third initial substrate in the third supporting area; and a portion of the pickup positions are located in the third supporting area, and
the transmission chain loop is configured to drive the plurality of pickup components to sequentially pass through the first supporting area, the second supporting area, the third supporting area and the first target-supporting area.

Such a configuration may pick up chips from different initial substrates and transfer them to the same target substrate. Such a configuration is particularly beneficial for achieving die bonding for a RGB display substrate.

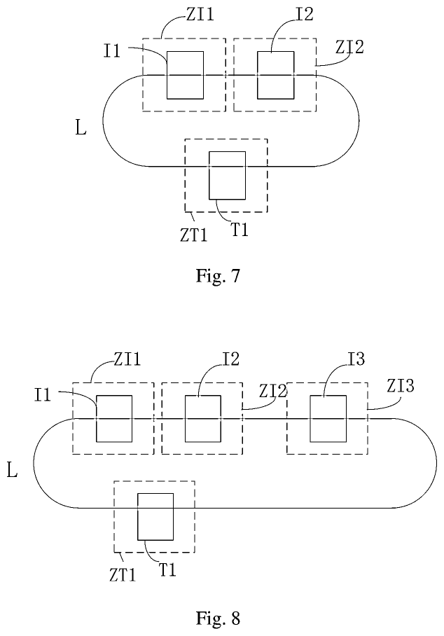

As shown in FIG. 8, the first initial substrate I1, the second initial substrate I2, the third initial substrate I3 and the first target substrate T1 may be in corresponding supporting area ZI1, ZI2, ZI3, ZT1 and may be movable. Pickup positions or put-down positions may be provided in corresponding supporting areas. The transmission chain loop passing through those positions may achieve the transfer of different kinds of chips from different initial substrates to the same target substrate. The first, second and third light-emitting chips may be for example R, G, B light-emitting chips respectively.

In an embodiment, the chip includes light-emitting chip serving as sub-pixels of a display device, wherein the light-emitting chips include first light-emitting chips and second light-emitting chips, and the first light-emitting chip and the second light-emitting chip have the same luminous color,
the chip transfer device is configured to transfer the first light-emitting chips from a first initial substrate to a first target substrate, and transfer the second light-emitting chips from a second initial substrate to the first target substrate,
the chip transfer device comprises a first supporting area and a second supporting area, wherein the chip transfer device supports the first initial substrate in the first supporting area, and the chip transfer device supports the second initial substrate in the second supporting area,
a portion of the pickup positions are located in the first supporting area, and a portion of the pickup positions are located in the second supporting area,
the chip transfer device comprises a target-supporting area, wherein the chip transfer device supports the first target substrate in the target-supporting area, and the put-down position(s) are located in the first target-supporting area, and
the transmission chain loop is configured to drive the plurality of pickup components to sequentially pass through the first supporting area, the second supporting area and the first target-supporting area.

Such a configuration may pick up the same kind of chips from different initial substrates and transfer them to the same target substrate. This may further increase the efficiency.

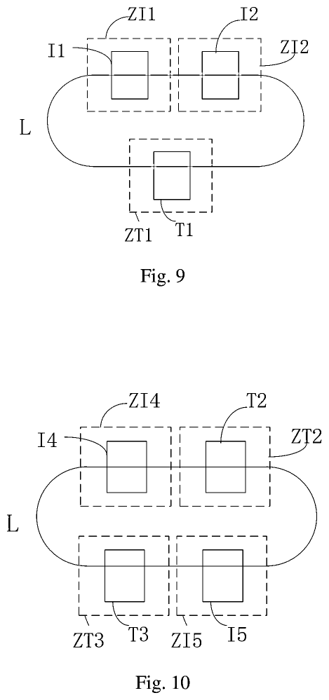

As shown in FIG. 9, the first initial substrate I1, the second initial substrate I2 and the first target substrate T1 may be in corresponding supporting areas ZI1, ZI2, ZT1, and may be movable. Pickup positions or put-down positions may be provided in corresponding supporting areas. The transmission chain loop passing through those positions may achieve the transfer of the same kind of chips from different initial substrates to the same target substrate.

In an embodiment, the chip transfer device is configured to transfer first chips from a fourth initial substrate to a second target substrate, and transfer second chips from a fifth initial substrate to a third target substrate,
the chip transfer device comprises a fourth supporting area and a fifth supporting area, where in the chip transfer device supports the fourth initial substrate in the fourth supporting area, and the chip transfer device supports the fifth initial substrate in the fifth supporting area,
the chip transfer device further comprises a second target-supporting area and a third target-supporting area, wherein the chip transfer device supports the second target substrate in the second target-supporting area, and the chip transfer device supports the third target substrate in the third target-supporting area,
a portion of the pickup positions are located in the fourth supporting area, and a portion of the pickup positions are located in the fifth supporting area,
a portion of the put-down positions are located in the second target-supporting area, and a portion of the put-down positions are located in the third target-supporting area,
wherein
the transmission chain loop is configured to drive the plurality of pickup components to sequentially pass through the fourth supporting area, the fifth supporting area, the second target-supporting area and the third target-supporting area, or sequentially pass through the fourth supporting area, the second target-supporting area, the fifth supporting area and the third target-supporting area.

Such a configuration may pick up chips from different initial substrates and transfer them to different target substrates. This may further increase the efficiency.

As shown in FIG. 10, the fourth initial substrate I4, the fifth initial substrate I5, the second target substrate T2 and the third target substrate T3 may be in corresponding supporting areas ZI4, ZI5, ZT2, ZT3, and may be movable. Pickup positions or put-down positions may be provided in corresponding supporting areas. The transmission chain loop passing through those positions may achieve the transfer of chips from different initial substrates to different target substrates. The fifth initial substrate I5 and the second target substrate T2 as well as corresponding supporting areas are interchangeable in sequence.

In an embodiment, the chip transfer device comprises a first movable stage which is disposed to correspond to the put-down positions.

In an embodiment, the chip transfer device comprises a second movable stage which is disposed to correspond to the pickup positions.

The movable stages are used to provide desired components for the put-down positions and the pickup positions. For example, solder paste sites or chips are provided respectively. The movable stages may be AOI-assisted support stages.

In an embodiment, the chip transfer device further comprises a rotatable negative pressure gas cylinder, wherein the rotatable negative pressure gas cylinder has an internal cavity;
the internal cavity of the rotatable negative pressure gas cylinder is connected to the pickup components through a pipeline, and is configured to provide a negative pressure to the pickup components; and
the rotatable negative pressure gas cylinder is rotated by movement of the pickup components via the pipeline.

In an embodiment, the chip transfer device further comprises:
a fixed cylinder, wherein the fixed cylinder has an internal cavity in gas communication with a negative pressure air pipe, and an inner wall of the fixed cylinder has an inward flange which has a through hole at its center;
wherein the rotatable gas cylinder is a suspended gas cylinder passing through the through hole, wherein the suspended gas cylinder is suspended on the flange through a ring-shaped ball bearing, such that the suspended gas cylinder is rotatable in the through hole, the internal cavity of the suspended negative pressure gas cylinder is joined to the internal cavity of the fixed cylinder by means of a sealing mechanism, and a side wall of the suspended gas cylinder is provided with a plurality of pipeline connection ports.

In an embodiment, the pipeline is a flexible pipeline.

In an embodiment, the sealing mechanism is a seal ring.

In an embodiment, the pipeline connection ports are radially extending pipes evenly distributed on the side wall along the circumferential direction.

An embodiment of the above rotatable gas cylinder may be as shown in FIG. 5.

In an embodiment, the pickup positions and the put-down positions are provided with an electromagnetic pickup component positioner,
wherein
the electromagnetic pickup component positioner has a second magnetic component, and
the pickup component has a first magnetic component, such that when the first magnetic component is attracted by the second magnetic component, the pickup component is temporarily fixed to the electromagnetic die bonding pen positioner,
wherein at least one of the first magnetic component and the second magnetic component is an electromagnetic component.

In an embodiment, the electromagnetic pickup component positioner has a recessed bottom and the pickup component has a protruded top, or, the electromagnetic pickup component positioner has a protruded bottom and the pickup component has a recessed top, such that when the second magnetic component is attracted by the first magnetic component, an outer surface of the top of the pickup component is adjacent to an inner surface of the bottom of the electromagnetic pickup component positioner, and preferably both the bottom and the top have a circular truncated cone-shaped structure.

In an embodiment, the chip transfer device is a Micro LED chip transfer device or a Mini LED chip transfer device.

In an embodiment, the driving gear is a stepping gear.

In an embodiment, the chip is a wafer or comprises a wafer.

In another aspect, the present disclosure provides a chip transfer method comprising:
driving a transmission chain loop with a plurality of pickup components fixed to pass through pickup position(s) and put-down position(s) with a driving gear, such that the pickup components arrive at the pickup positions and the put-down positions, and
picking up a chip at the pickup position, and putting down the chip at the put-down position.

The chip transfer method of the present disclosure uses the transmission chain loop to cooperate with the driving gear to achieve an efficient chip transfer.

In an embodiment, the transmission chain loop passes through at least one group of put-down positions comprising a plurality of put-down positions on a first straight line,
wherein chips are put down respectively at the put-down positions of the group of put-down positions simultaneously.

In an embodiment, the chip includes light-emitting chips serving as sub-pixels of a display device, wherein the light-emitting chips include first light-emitting chips having the same luminous color,
the chip transfer method further comprises transferring the first light-emitting chips from a first initial substrate to a first target substrate, such that the first light-emitting chips are periodically arranged on the first target substrate along a first direction,
the first straight line extends along the first direction, and
a distance between two adjacent put-down positions in the group of put-down positions is equal to an integer multiple of an arrangement period of the first light-emitting chips.

In an embodiment, the transmission chain loop passes through at least one group of pickup positions comprising a plurality of pickup positions on a second straight line.

In an embodiment, the chip transfer method further comprises transferring the chips from a first initial substrate to a first target substrate, such that the chips are periodically arranged on the first initial substrate along a second direction;
the second straight line extends along the second direction; and
a distance between two adjacent pickup positions in the group of pickup positions is equal to an integer multiple of an arrangement period of the chips.

In an embodiment, the chip includes light-emitting chips serving as sub-pixels of a display device, wherein the light-emitting chips include first light-emitting chips and second light-emitting chips, and the first light-emitting chips and the second light-emitting chips have different luminous colors,
the chip transfer method further comprises transferring the first light-emitting chips from a first initial substrate to a first target substrate, and transferring the second light-emitting chips from a second initial substrate to the first target substrate,
the first initial substrate is supported in a first supporting area, the second initial substrate is supported in a second supporting area, and the first target substrate is supported in a first target-supporting area,
a portion of the pickup positions are located in the first supporting area, a portion of the pickup positions are located in the second supporting area, and the put-down position(s) are located in the first target-supporting area, and
the chip transfer method further comprises driving the plurality of pickup components to sequentially pass through the first supporting area, the second supporting area and the first target-supporting area with the transmission chain loop.

In an embodiment, the light-emitting chip further comprises a third light-emitting chip, wherein the first light-emitting chips, the second light-emitting chips and the third light-emitting chips have different luminous colors,
the chip transfer method further comprises transferring the third light-emitting chips from a third initial substrate to the first target substrate,
the third initial substrate is supported in a third supporting area, and a portion of the pickup positions are located in the third supporting area, and
the chip transfer method further comprises driving the plurality of pickup components to sequentially pass through the first supporting area, the second supporting area, the third supporting area and the first target-supporting area with the transmission chain loop.

In an embodiment, the chip includes light-emitting chips serving as sub-pixels of a display device, wherein the light-emitting chips include first light-emitting chips and second light-emitting chips, and the first light-emitting chips and the second light-emitting chips have the same luminous color,
the chip transfer method further comprises transferring the first light-emitting chips from a first initial substrate to a first target substrate, and transferring the second light-emitting chip from a second initial substrate to the first target substrate,
the first initial substrate is supported in a first supporting area, the second initial substrate is supported in a second supporting area, and the first target substrate is supported in a first target-supporting area,
a portion of the pickup positions are located in the first supporting area, a portion of the pickup positions are located in the second supporting area, and the put-down position(s) are located in the first target-supporting area, and
the chip transfer method further comprises driving the plurality of pickup components to sequentially pass through the first supporting area, the second supporting area and the first target-supporting area with the transmission chain loop.

In an embodiment, the chip transfer method further comprises transferring first chips from a fourth initial substrate to a second target substrate, and transferring second chips from a fifth initial substrate to a third target substrate,
the fourth initial substrate is supported in a fourth supporting area, the fifth initial substrate is supported in a fifth supporting area, and the second target substrate is supported in a first target-supporting area,
a portion of the pickup positions are located in the fourth supporting area, and a portion of the pickup positions are located in the fifth supporting area,
a portion of the put-down positions are located in the second target-supporting area, and a portion of the put-down positions are located in the third target-supporting area,
wherein
the chip transfer method further comprises driving the plurality of pickup components to sequentially pass through the fourth supporting area, the fifth supporting area, the second target-supporting area and the third target-supporting area, or, sequentially pass through the fourth supporting area, the second target-supporting area, the fifth supporting area and the third target-supporting area.

The advantage of the above embodiment is that the combination of the put-down position and the pickup position with the target substrate and the initial substrate may be selected as needed, such that the chip transfer method of the present disclosure may be flexibly used for various transfer purposes.

In an embodiment, a position of the pickup component is fixed with a positioner after the pickup component arrives at the pickup position;
the chip is aligned with the position of the pickup component by using an automated optical inspection machine, and
the chip is picked up,
and
a position of the pickup component is fixed with a positioner after the pickup component arrives at a put-down position;
a put-down target is aligned with the position of the pickup component by using an automated optical inspection machine; and
the chip is put down at the put-down target.

In an embodiment, picking up the chip comprises applying a negative pressure to the pickup component to take the chip by suction, and
putting down the chip comprises contacting the chip with a solder paste and removing the negative pressure.

In an embodiment, the driving gear drives the transmission chain loop step by step.

In an embodiment, the chip is a wafer or comprises a wafer.

In yet another aspect, the present disclosure provides a magnetic die bonding pen comprising:
a tubular pen cylinder, and
a columnar pen core in the tubular pen cylinder, the columnar pen core having a first end, a second end and a side wall extending between the first end and the second end,
wherein the columnar pen core comprises:
   a first magnetic component which is a permanent magnetic component or comprises a metal capable of being attracted by a magnet;
   a suction nozzle at the first end,
   a pipeline connector on the side wall, and
a gas path extending inside the side wall and connecting the suction nozzle and the pipeline connector.

The magnetic die bonding pen is suitably used as the pickup component in the present disclosure.

In an embodiment, the magnetic die bonding pen further comprises a convex or concave structure, and preferably a circular truncated cone-shaped convex or concave structure, at the second end.

In an embodiment, the magnetic die bonding pen further comprises:
a restoring spring forming an axial connection between the tubular pen cylinder and the columnar pen core.

In an embodiment, a side wall of the tubular pen cylinder has an axially extending groove, and
the pipeline connector passes through the groove to an outside of the tubular pen cylinder.

In an embodiment, an electromagnetic valve is provided at the pipeline connector outside the tubular pen cylinder.

### EXAMPLES

### Example 1

The chain-type die bonding device as shown in FIG. 1 and FIG. 2 was used to carry out the chip pickup-die bonding process. The device had a suspended negative pressure gas cylinder as shown in FIG. 5 and an electromagnetic die bonding pen positioner as shown in FIG. 6.

In the operation of the device, first, when the die bonding head moved above the LED array of the initial substrate disc, the electromagnet of the electromagnetic die bonding pen positioner at the chip pickup position was powered on to draw the upper circular truncated cone convex top wall of the die bonding pen into the circular truncated cone-shaped concave bottom, thereby completing the accurate positioning of the die bonding pen. The movable stage supporting the initial substrate moved below the die bonding pen with the AOI-assisted positioning. The stage cooperated with the die bonding pen to press down the die bonding pen. The gas path in the die bonding pen was opened to complete the chip pickup action. Driven by the stepping gear and the transmission chain, the die bonding pen which had picked up the chip moved along the transmission chain loop step by step to the die bonding position on the target substrate. The accurate positioning of the die bonding pen at the die bonding position was consistent with the positioning method at the chip pickup position. When the die bonding pen moved above the pad for die bonding on the target substrate, the electromagnet of the electromagnetic die bonding pen positioner at the die bonding position was powered on to draw the upper circular truncated cone convex top wall of the die bonding pen into the circular truncated cone-shaped concave bottom, thereby completing the accurate positioning of the die bonding pen. The movable stage supporting the target substrate moved below the die bonding pen with the AOI-assisted positioning. The stage cooperated with the die bonding pen to press down the die bonding pen to come into contact with the solder paste pad on the target substrate. The gas path in the die bonding pen was cut off, such that the chip was adhered to the pad so as to complete the die bonding action. When the transmission chain advances step by step, the flexible gas pipe continuously rotated with the rotation of the die bonding pen, thereby driving the suspended negative pressure gas cylinder to rotate together inside the fixed cylinder wall.

In the experiment, a transfer speed of 30 chips/second was achieved with a satisfactory die bonding yield.

### Example 2

Using the configuration as shown in FIG. 3, a process similar to Example 1 was used to carry out simultaneous pickup by suction, transfer and mounting of a plurality of chips from one initial substrate to one target substrate, with each group of chip pickup positions/die bonding positions comprising four positions. In the experiment, a transfer speed of 120 chips/second was achieved with a satisfactory die bonding yield.

### Example 3

Using the configuration as shown in FIG. 4, a process similar to Example 1 was used to carry out simultaneous pickup by suction, transfer and mounting of a plurality of chips from two initial substrates to two target substrates, with each group of chip pickup positions/die bonding positions comprising four positions. In the experiment, a transfer speed of 240 chips/second was achieved with a satisfactory die bonding yield.

As compared to the present disclosure, the swing-arm-type LED chip die bonder in the related technologies generally has a chip transfer speed of 10-20 chips/second. Thus, the method of the present disclosure greatly improves the overall efficiency.

The above descriptions are only particular embodiments of the present disclosure, but the protection scope of the present disclosure is not limited thereto. Within the technical scope disclosed in the present disclosure, one skilled in the art can readily envisage variations and alternatives, and all of them are covered by the protection scope of the present disclosure. Therefore, the protection scope of the present disclosure should be defined by the appended claims.

1. A chip transfer device comprising:
a transmission chain loop passing through pickup positions and put-down positions;
a driving gear cooperating with the transmission chain loop; and
a plurality of pickup components disposed on the transmission chain loop,
wherein the driving gear is configured to drive the transmission chain loop such that the pickup components arrive at the pickup positions and the put-down positions, and the pickup component is configured to pick up a chip at a pickup position and put down the chip at a put-down position,
wherein
the transmission chain loop passes through at least one group of put-down positions comprising a plurality of put-down positions on a first straight line.

2. (canceled)

3. The chip transfer device according to claim 1, wherein the chips includes light-emitting chips serving as sub-pixels of a display device, wherein the light-emitting chips include first light-emitting chips,
the chip transfer device is configured to transfer the first light-emitting chips from a first initial substrate to a first target substrate, such that the first light-emitting chips are periodically arranged on the first target substrate along a first direction,
the first straight line extends along the first direction, and
a distance between two adjacent put-down positions in the group of put-down positions is equal to an integer multiple of an arrangement period of the first light-emitting chips.

4. The chip transfer device according to claim 1, wherein
the transmission chain loop passes through at least one group of pickup positions comprising a plurality of pickup positions on a second straight line.

5. The chip transfer device according to claim 4, wherein
the chip transfer device is configured to transfer the chips from a first initial substrate to a first target substrate, such that the chips are periodically arranged on the first initial substrate along a second direction,
the second straight line extends along the second direction, and
a distance between two adjacent pickup positions in the group of pickup positions is equal to an integer multiple of an arrangement period of the chips.

6. The chip transfer device according to claim 1, wherein the chip includes light-emitting chips serving as sub-pixels of a display device, wherein the light-emitting chips include first light-emitting chips and second light-emitting chips, and the first light-emitting chips and the second light-emitting chips have different luminous colors,
the chip transfer device is configured to transfer the first light-emitting chips from a first initial substrate to a first target substrate, and transfer the second light-emitting chips from a second initial substrate to the first target substrate,
the chip transfer device comprises a first supporting area and a second supporting area, wherein the chip transfer device supports the first initial substrate in the first supporting area, and the chip transfer device supports the second initial substrate in the second supporting area,
a portion of the pickup positions are located in the first supporting area, and a portion of the pickup positions are located in the second supporting area,
the chip transfer device comprises a target-supporting area, wherein the chip transfer device supports the first target substrate in the target-supporting area, and the put-down position(s) are located in the target-supporting area, and
the transmission chain loop is configured to drive the plurality of pickup components to sequentially pass through the first supporting area, the second supporting area and the first target-supporting area.

7. The chip transfer device according to claim 6, wherein the light-emitting chips further include third light-emitting chips, wherein the first light-emitting chips, the second light-emitting chips and the third light-emitting chips have different luminous colors,
the chip transfer device is configured to further transfer the third light-emitting chips from a third initial substrate to the first target substrate,
the chip transfer device further comprises a third supporting area, wherein the chip transfer device supports the third initial substrate in the third supporting area; and a portion of the pickup positions are located in the third supporting area, and
the transmission chain loop is configured to drive the plurality of pickup components to sequentially pass through the first supporting area, the second supporting area, the third supporting area and the first target-supporting area.

8. The chip transfer device according to claim 1, wherein the chip includes light-emitting chip serving as sub-pixels of a display device, wherein the light-emitting chips include first light-emitting chips and second light-emitting chips, and the first light-emitting chip and the second light-emitting chip have the same luminous color,
the chip transfer device is configured to transfer the first light-emitting chips from a first initial substrate to a first target substrate, and transfer the second light-emitting chips from a second initial substrate to the first target substrate,
the chip transfer device comprises a first supporting area and a second supporting area, wherein the chip transfer device supports the first initial substrate in the first supporting area, and the chip transfer device supports the second initial substrate in the second supporting area,
a portion of the pickup positions are located in the first supporting area, and a portion of the pickup positions are located in the second supporting area,
the chip transfer device comprises a target-supporting area, wherein the chip transfer device supports the first target substrate in the target-supporting area, and the put-down position(s) are located in the first target-supporting area, and
the transmission chain loop is configured to drive the plurality of pickup components to sequentially pass through the first supporting area, the second supporting area and the first target-supporting area.

9. The chip transfer device according to claim 1, wherein
the chip transfer device is configured to transfer first chips from a fourth initial substrate to a second target substrate, and transfer second chips from a fifth initial substrate to a third target substrate,
the chip transfer device comprises a fourth supporting area and a fifth supporting area, where in the chip transfer device supports the fourth initial substrate in the fourth supporting area, and the chip transfer device supports the fifth initial substrate in the fifth supporting area,
the chip transfer device further comprises a second target-supporting area and a third target-supporting area, wherein the chip transfer device supports the second target substrate in the second target-supporting area, and the chip transfer device supports the third target substrate in the third target-supporting area,
a portion of the pickup positions are located in the fourth supporting area, and a portion of the pickup positions are located in the fifth supporting area,
a portion of the put-down positions are located in the second target-supporting area, and a portion of the put-down positions are located in the third target-supporting area,
wherein
the transmission chain loop is configured to drive the plurality of pickup components to sequentially pass through the fourth supporting area, the fifth supporting area, the second target-supporting area and the third target-supporting area, or sequentially pass through the fourth supporting area, the second target-supporting area, the fifth supporting area and the third target-supporting area.

10. The chip transfer device according to claim 1, wherein the chip transfer device comprises a first movable stage which is disposed to correspond to the put-down positions.

11. The chip transfer device according to claim 1, wherein the chip transfer device comprises a second movable stage which is disposed to correspond to the pickup positions.

12. The chip transfer device according to claim 1, wherein the chip transfer device further comprises a rotatable negative pressure gas cylinder, wherein the rotatable negative pressure gas cylinder has an internal cavity;
the internal cavity of the rotatable negative pressure gas cylinder is connected to the pickup components through a pipeline, and is configured to provide a negative pressure to the pickup components; and
the rotatable negative pressure gas cylinder is rotated by movement of the pickup components via the pipeline.

13. The chip transfer device according to claim 12, wherein the chip transfer device further comprises:
a fixed cylinder, wherein the fixed cylinder has an internal cavity in gas communication with a negative pressure air pipe, and the fixed cylinder comprises a recess formed by inward extending of an inner wall; and
a plurality of balls;
wherein
the rotatable negative pressure gas cylinder is sleeved in the fixed cylinder, and has a first end away from the negative pressure air pipe and a second end close to the negative pressure air pipe, and the internal cavity of the rotatable negative pressure gas cylinder communicates the first end and the second end;
an outer side wall of the rotatable negative pressure gas cylinder comprises a protrusion which is fitted into the recess,
the internal cavity of the rotatable negative pressure gas cylinder is slidably joined to the internal cavity of the fixed cylinder, and is sealed at a joint with a seal ring,
the rotatable negative pressure gas cylinder has a plurality of pipeline connection ports at the first end for connecting to the pipeline, and
the recess and the protrusion have opposite grooves forming a first groove structure, and the first groove structure serves as a first sliding track to accommodate the balls to form a ball bearing.

14. The chip transfer device according to claim 12, wherein the recess and the protrusion also have opposite grooves forming a second groove structure, and the second groove structure serves as a second sliding track to accommodate the balls to form a ball bearing, wherein the first sliding track and the second sliding track are respectively located on a side of the recess close to the first end and a side of the recess close to the second end.

15. The chip transfer device according to claim 12, wherein opposite grooves forming a third groove structure are provided respectively on the outer side wall of the rotatable negative pressure gas cylinder and the inner wall of the fixed cylinder, and the third groove structure accommodates the seal ring surrounding the rotatable negative pressure gas cylinder,
and/or
wherein the seal ring is further away from the first end than the protrusion.

16. (canceled)

17. The chip transfer device according to claim 1, wherein the pickup positions and the put-down positions are provided with an electromagnetic pickup component positioner,
wherein
the electromagnetic pickup component positioner has a second magnetic component, and
the pickup component has a first magnetic component, such that when the first magnetic component is attracted by the second magnetic component, the pickup component is temporarily fixed to the electromagnetic die bonding pen positioner,
wherein at least one of the first magnetic component and the second magnetic component is an electromagnetic component.

18. The chip transfer device according to claim 17, wherein
the electromagnetic pickup component positioner has a recessed bottom and the pickup component has a protruded top, or, the electromagnetic pickup component positioner has a protruded bottom and the pickup component has a recessed top, such that when the second magnetic component is attracted by the first magnetic component, an outer surface of the top of the pickup component is adjacent to an inner surface of the bottom of the electromagnetic pickup component positioner, and preferably both the bottom and the top have a circular truncated cone-shaped structure.

19. The chip transfer device according to claim 1, wherein
the chip transfer device is a Micro LED chip transfer device or a Mini LED chip transfer device.

20. (canceled)

21. The chip transfer device according to claim 1, wherein the chip is a wafer or comprises a wafer.

22. A chip transfer method comprising:
driving a transmission chain loop with a plurality of pickup components fixed to pass through pickup positions and put-down positions with a driving gear, such that the pickup components arrive at the pickup positions and the put-down positions, and
picking up a chip at the pickup position, and putting down the chip at the put-down position,
wherein
the transmission chain loop passes through at least one group of put-down positions comprising a plurality of put-down positions on a first straight line,
wherein chips are put down respectively at the put-down positions of the group of put-down positions simultaneously.

23-34. (canceled)

35. A magnetic die bonding pen comprising:
a tubular pen cylinder, and
a columnar pen core in the tubular pen cylinder, the columnar pen core having a first end, a second end and a side wall extending between the first end and the second end,
wherein the columnar pen core comprises:
a first magnetic component which is a permanent magnetic component or comprises a metal capable of being attracted by a magnet;
a suction nozzle at the first end,
a pipeline connector on the side wall, and
a gas path extending inside the side wall and connecting the suction nozzle and the pipeline connector.

36-39. (canceled)
